(19) United States
(12) Patent Application Publication
(10) Pub. No.: US 2026/0059970 A1
(43) Pub. Date: Feb. 26, 2026

(54) DISPLAY DEVICE

(71) Applicant: SK hynix Inc., Icheon-si (KR)

(72) Inventor: Yu Shin RYU, Icheon-si (KR)

(21) Appl. No.: 19/005,661

(22) Filed: Dec. 30, 2024

(30) Foreign Application Priority Data
Aug. 20, 2024 (KR) 10-2024-0110895

(51) Int. Cl. H10K 59/80; H10K 59/12; H10K 59/35

(52) U.S. Cl. CPC H10K 59/80518; H10K 59/1201; H10K 59/35

(57) ABSTRACT

Display devices and methods for manufacturing display devices are disclosed. In an embodiment, a display device includes a plurality of sub-pixels disposed over a substrate and configured to emit light, the plurality of sub-pixels comprising a first sub-pixel, a second sub-pixel and a third sub-pixel, wherein the first, second, and third sub-pixels include first, second, and third reflective electrodes, respectively, to reflect light. The first reflective electrode and the second reflective electrode may have a basket shape.

### CROSS REFERENCE TO RELATED APPLICATION

This patent document claims priority to and the benefit of Korean Patent Application No. 10-2024-0110895, filed on Aug. 20, 2024, the disclosure of which is incorporated herein by reference in its entirety.

### TECHNICAL FIELD

The disclosed technology relates to a display device.

### BACKGROUND

As the information society develops, the demand for various display devices that show images is increasing, and various types of display devices, such as liquid crystal displays (LCDs) and organic light emitting diode displays (OLEDs) are being utilized.

Among such display devices, OLEDs are self-emissive, offering superior viewing angles and contrast ratios compared to LCDs. OLEDs do not require a separate backlight, allowing for lighter and thinner designs, and they have the advantage of lower power consumption. In addition, OLED displays can be driven by low-voltage direct current, have fast response time, and offer lower manufacturing costs.

Recently, the demand for display devices utilizing OLED has been increasing for applications such as augmented reality (AR), virtual reality (VR), or for display devices that require ultra-high resolution.

### SUMMARY

The disclosed technology can be implemented in some embodiments to provide a display device that includes a transparent layer with improved transmittance.

The disclosed technology can be implemented in some embodiments to provide a display device with improved light efficiency by increasing reflectance through reflective electrodes.

The disclosed technology can be implemented in some embodiments to provide a display device that prevents light mixing or color mixing by forming trenches at the boundaries of adjacent sub-pixels.

The disclosed technology can be implemented in some embodiments to provide a display device with improved light efficiency by increasing light collection rate through a basket-shaped reflective electrode.

The disclosed technology can be implemented in some embodiments to provide a display device with improved characteristics related to light mixing or color mixing between adjacent sub-pixels by using a basket-shaped reflective electrode.

The disclosed technology can be implemented in some embodiments to provide a display device that can reduce thickness variations in reflective electrodes by forming the reflective electrodes of each sub-pixel through the same process.

The disclosed technology can be implemented in some embodiments to provide a display device that can reduce the number of masks and simplify the process by etching a reflective electrode and a first electrode and forming trenches in a third sub-pixel using the same photo resist.

The disclosed technology can be implemented in some embodiments to provide a method of manufacturing a display device that can reduce thickness variations in the reflective electrodes by forming the reflective electrodes of each sub-pixel through the same process.

The disclosed technology can be implemented in some embodiments to provide a method of manufacturing a display device that can reduce the number of masks and simplify the process by etching a reflective electrode and a third anode electrode and forming trenches in a third sub-pixel using the same photo resist.

In some embodiments of the disclosed technology, a display device may include a plurality of sub-pixels disposed over a substrate and configured to emit light, the plurality of sub-pixels comprising a first sub-pixel, a second sub-pixel and a third sub-pixel, wherein the first, second, and third sub-pixels include first, second, and third reflective electrodes, respectively, to reflect light, wherein the first reflective electrode and the second reflective electrode have a basket shape.

In some embodiments of the disclosed technology, a display device may include a substrate comprising a first sub-pixel, a second sub-pixel and a third sub-pixel; a first reflective electrode of the first sub-pixel; a second reflective electrode of the second sub-pixel; and a third reflective electrode of the third sub-pixel. The first reflective electrode and the second reflective electrode may have a basket shape.

In some embodiments of the disclosed technology, a method for manufacturing a display device may include: forming, on a substrate, first to third sub-pixels including a light emitting area configured to emit light and a non-light emitting area that does not emit light; forming first to fifth insulating layers on the first to third sub-pixels, wherein the first insulating layer is disposed on the first to third sub-pixels, the second insulating layer is disposed on the first insulating layer, the third insulating layer is disposed on the second insulating layer, the fourth insulating layer is disposed on the third insulating layer, and the fifth insulating layer is disposed on the fourth insulating layer; forming a protective electrode layer on the fifth insulating layer; etching the protective electrode layer and the third to fifth insulating layers in the first sub-pixel; etching the protective electrode layer and the fifth insulating layer in the second sub-pixel; sequentially forming a reflective electrode layer, a sixth insulating layer and a seventh insulating layer on the protective electrode layer and the fifth insulating layer; exposing the sixth insulating layer in the non-light emitting area by polishing the seventh insulating layer in the first to third sub-pixels; exposing the protective electrode layer in the non-light emitting area by removing the sixth insulating layer and the seventh insulating layer in the first to third sub-pixels; forming a first anode electrode of the first sub-pixel, a second anode electrode of the second sub-pixel and a third anode electrode of the third sub-pixel on the seventh insulating layer; and simultaneously forming a first reflective electrode of the first sub-pixel, a second reflective electrode of the second sub-pixel and a third reflective electrode of the third sub-pixel by etching the protective electrode layer and the reflective electrode layer in the non-light emitting areas of the first to third sub-pixels, and the first reflective electrode and the second reflective electrode may have a basket shape.

In some embodiments of the disclosed technology, the transparent layer may have very thin thickness, thereby increasing the transmittance of the transparent layer.

In some embodiments of the disclosed technology, the common light emitting layer severed at the trench by forming the trench at the boundaries of adjacent sub-pixels. This allows for an improvement in lateral leakage current between adjacent sub-pixels.

In some embodiments of the disclosed technology, light concentration or light collection rate may be increased by applying a basket-shaped reflective electrode, thereby improving light efficiency and preventing light mixing or color mixing between adjacent sub-pixels.

In some embodiments of the disclosed technology, by forming the reflective electrodes of each sub-pixel through the same process, thickness variations in reflective electrodes can be reduced.

In some embodiment of the disclosed technology, by using the same photo resist for etching the reflective electrode, etching the first electrode, and forming trenches, the number of masks can be reduced and the process can be simplified.

### BRIEF DESCRIPTION OF THE DRAWINGS

FIG. 1 is a plane view illustrating a display device based on an embodiment.

FIG. 2 is a cross-sectional view taken along A-A′ of FIG. 1.

FIG. 3 is a cross-sectional view taken along B-B′ of FIG. 1.

FIG. 4 is a cross-sectional view taken along C-C′ of FIG. 1.

FIG. 5 is a cross-sectional view illustrating an organic light emitting display according to an example of FIG. 2.

FIG. 6 is a cross-sectional view illustrating an organic light emitting display according to a modified example of FIG. 2.

FIGS. 7 to 29 are cross-sectional views illustrating process steps of a method for manufacturing a display device based on an embodiment.

FIG. 30 is a cross-sectional view of a display device based on an embodiment.

FIG. 31 is a cross-sectional view of a display device based on an embodiment.

FIG. 32 is a cross-sectional view of a display device based on an embodiment.

### DETAILED DESCRIPTION

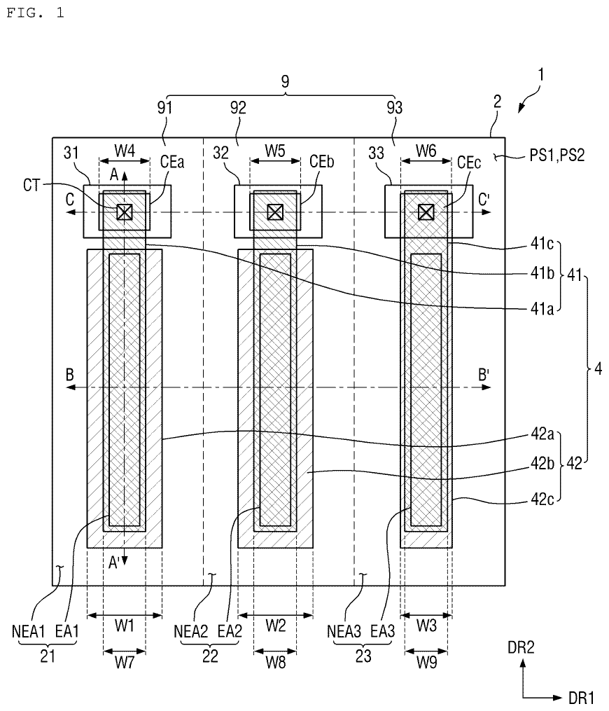

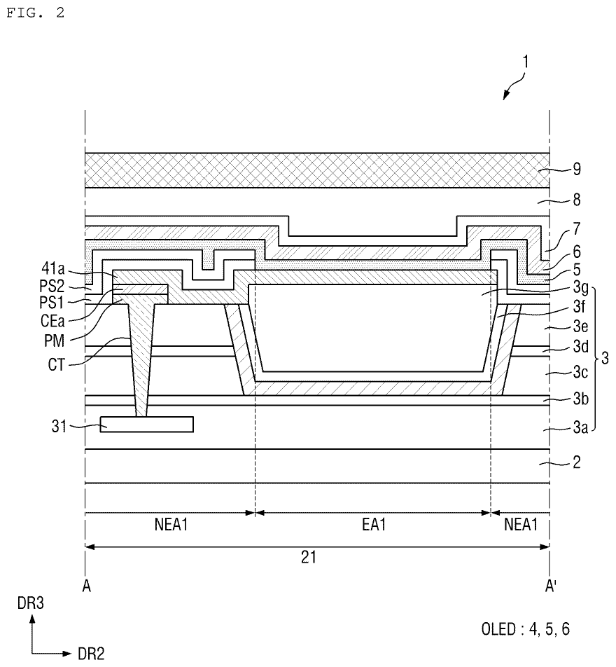

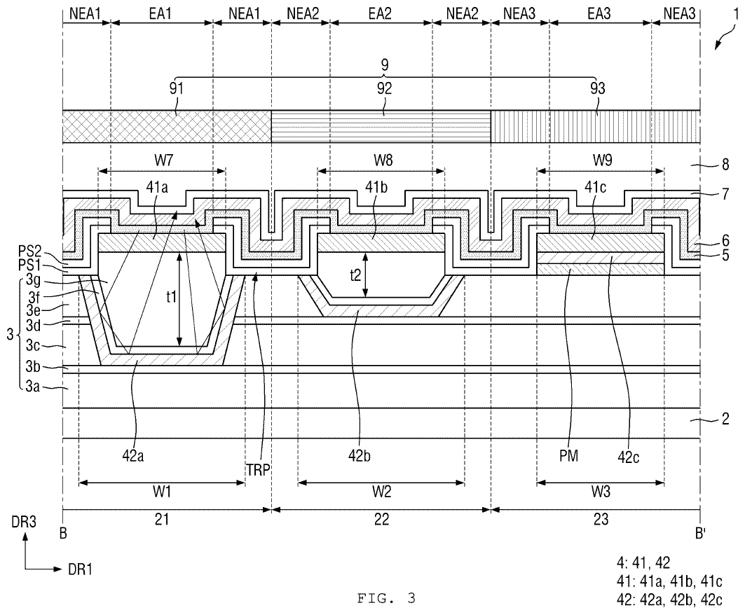

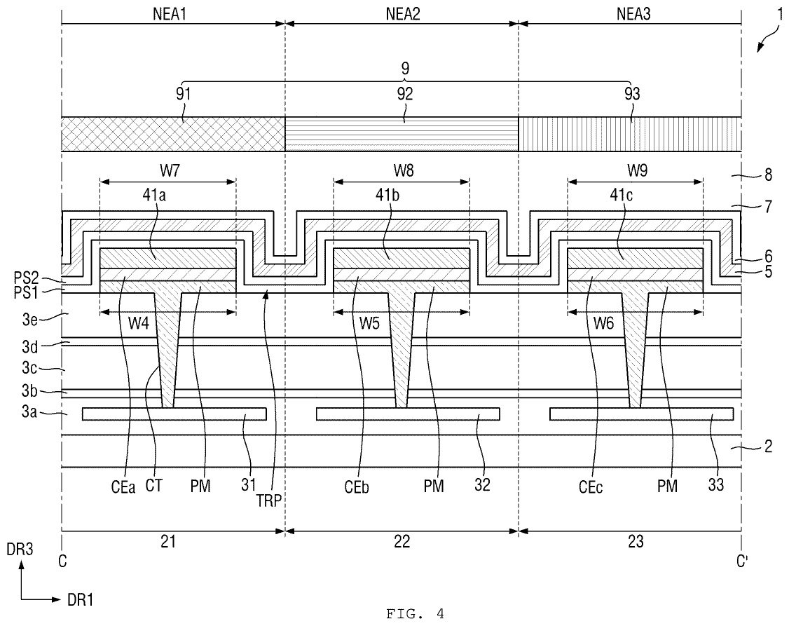

FIG. 1 is a plane view illustrating a display device based on an embodiment. FIG. 2 is a cross-sectional view taken along A-A′ of FIG. 1. FIG. 3 is a cross-sectional view taken along B-B′ of FIG. 1. FIG. 4 is a cross-sectional view taken along C-C′ of FIG. 1.

Referring to FIGS. 1 to 4, the display device 1 based on an embodiment may include a substrate 2, a firs electrode 4, a common light emitting layer 5 and a second electrode 6.

A plurality of sub-pixels 21, 22 and 23 are formed on the substrate 2. The plurality of sub-pixels 21, 22 and 23 may form one pixel. A plurality of pixels may be formed on the substrate 2 to form a pixel array to display images. In some embodiments, the term “pixel” can be used to indicate an element of a display device that emits light in response to an electric current.

The plurality of sub-pixels 21, 22 and 23 may include a first sub-pixel 21, a second sub-pixel 22 and a third sub-pixel 23 that are arranged relative to one another in a spatial sequence or pattern to collectively form one pixel for the display device. For example, in the example shown in FIG. 1, the first sub-pixel 21, the second sub-pixel 22 and the third sub-pixel 23 are arranged in sequence along a line, so that the second sub-pixel 22 may be disposed adjacent to one side of the first sub-pixel 21, for example, on the left side of the first sub-pixel 21, and the third sub-pixel 23 may be disposed adjacent to one side of the second sub-pixel 22, for example, the left side of the second sub-pixel 22.

In some embodiments, the expression that two sub-pixels are disposed adjacent to each other may be used to indicate that no other sub-pixels are disposed between the two sub-pixels.

The first sub-pixel 21 may be configured to emit red light R, the second sub-pixel 22 may be configured to emit green light G, and the third sub-pixel 23 may be configured to emit blue light B. However, the disclosed technology is not limited thereto.

Although FIG. 1 the pixel as including only three sub-pixels 21, 22 and 23, the disclosed technology is not limited thereto. In some embodiments, the pixel may include four sub-pixels. When the pixel includes four sub-pixels, a fourth sub-pixel may be further provided to emit white light W.

In some embodiments, each of the first to third sub-pixels 21, 22 and 23 may have the same size. For example, each of the first to third sub-pixels 21, 22 and 23 may have the same width and the same height. Here, the term “width” may represent a length in a horizontal direction (e.g., a first direction DR1 in FIG. 1), the term “height” may represent a length in a vertical direction (e.g., a second direction DR2 in FIG. 1) perpendicular to the width, and the term “upper direction” may represent a length in in a thickness direction (e.g., a third direction DR3 toward an insulating layer 3 from the substrate 2 in FIG. 2). However, the disclosed technology is not limited thereto.

A first protective layer PS1 and a second protective layer PS2 may be disposed between each two of the first sub-pixel 21, the second sub-pixel 22 and the third sub-pixel 23. The first protective layer PS1 and the second protective layer PS2 may function as banks defining light emitting areas EA1, EA2 and EA3 of the sub-pixels 21, 22 and 23.

Each of the sub-pixels 21, 22 and 23 may include light emitting areas EA1, Ea2 and EA3 and non-light emitting areas NEA1, NEA2 and NEA3. The first sub-pixel 21 may include a first light emitting area EA1 and a first non-light emitting area NEA1 adjacent to the first light emitting area EA1. The second sub-pixel 22 may include a second light emitting area EA2 and a second non-light emitting area NEA2 adjacent to the second light emitting area EA2. The third sub-pixel 23 may include a third light emitting area EA3 and a third non-light emitting area NEA3 adjacent to the third light emitting area EA3. Each of the light emitting areas EA1, EA2 and EA3 may be the areas exposed from protective layers PS1 and PS2 of anode electrodes 41a, 41b, 41c.

The first electrode 3 is patterned for each individual sub-pixel 21, 22 and 23. In other words, one first electrode 4 may be formed in the first sub-pixel 21, another first electrode 4 may be formed in the second sub-pixel 22, and the third electrode 4 may be formed in the third sub-pixel 23. The first electrode 4 may function as an anode of the display device 1. The protective layers PS1 and PS2 may cover edges of the first electrodes 4 disposed in the first to third sub-pixels 21, 22 and 23, respectively, so that the first sub-pixel 21, the second sub-pixel 22 and the third sub-pixel 23 may be distinguished.

The display device 1 may further improve light extraction efficiency by using micro-cavity characteristics through the inclusion of reflective electrodes 42 with varying surface heights.

The micro-cavity characteristics refers to the phenomenon where constructive inference occurs, amplifying light when the distance between the reflective electrode 42 and the second electrode 6 is an integer multiple of half the wavelength of the light emitted from the sub-pixel. When the reflection and re-reflection process is repeated between reflective electrode 42 and the second electrode 6, the degree of light amplification continuously increases, thereby improving the external light extraction efficiency.

The common light emitting layer 5 may emit white light. For example, the common light emitting layer 5 may have a two-stack structure including a blue light emitting layer, a yellow-green light emitting layer, and a charge generation layer, or a three-stack structure including a blue light emitting layer, a green light emitting layer, a red light emitting layer and a charge generation layer, to emit white light. However, the disclosed technology is not limited thereto, and if it can emit white light, the common light emitting layer 5 may be configured with multiple layers exceeding three stacks.

The common light emitting layer 5 may be provided as a common layer disposed over the entire first to third sub-pixels 21, 22 and 23.

The second electrode 6 may be configured to form an electric field with the first electrode 4 and may function as a cathode. The second electrode 6 may be disposed on an upper surface of the common light emitting layer 5, opposite to a lower surface of the common light emitting layer 5 configured to contact the first electrode 4, and it may be provided as a common layer disposed over the entire first to third sub-pixels 21, 22 and 23.

The second electrode 6 may be configured as the second electrode in a top emitting system, and as the first electrode including a reflective material in a bottom emission system.

A color filter layer 9 may be provided for each of the first to third sub-pixels 21, 22 and 23 and configured to block specific colors from the light emitted from the light emitting layer of each sub-pixel. A first color filter 91 provided for the first sub-pixel 21 may block colors except red light R. In this case, the first color filter 91 may be configured as a red color filter. The second color filter 92 provided for the second sub-pixel 22 may block colors except green light G. In this case, the second color filter 92 may be configured as a green color filter. The third color filter 93 provided in the third sub-pixel 23 may block colors except blue light B. In this case, the third color filter 93 may be configured as a blue color filter. However, the disclosed technology is not limited thereto the above examples.

The first to third color filters 91, 92 and 93 provided in each of the first to third sub-pixels 21, 22 and 23 may have the same size as the size of each sub-pixel, or may be scaled down or enlarged in a certain proportion relative to the size of each sub-pixel.

Transistors 31, 32 and 33 may be disposed in the non-light emitting areas NEA1, NEA2 and NEA3 of each sub-pixel 21, 22 and 23, respectively. For example, the transistors 31, 32 and 33 may be disposed on one second-direction side of the reflective electrodes 42a, 42b and 42c, but the disclosed technology is not limited thereto. The anode electrodes 41a, 41b and 41c may be electrically connected with corresponding transistors 31, 32 and 33 through connection electrodes CEa, CEb and CEc, a protective electrode PM and a contact hole CT, which are disposed in the sub-pixels 21, 22 and 23. A third connection electrode CEc may be integrally formed with a third reflective electrode 42c, while first and second connection electrodes CEa and CEb may be spaced apart from the reflective electrodes 42a and 42b, respectively.

Each of the reflective electrodes 42a, 42b and 42c may have a first width W1, a second width W2 and a third width W3. Each of the connection electrodes CEa, CEb and CEc may have a fourth width W4, a fifth width W5 and a sixth width W6. Each of the anode electrodes 41a, 41b and 41c may have a seventh width W7, an eighth width W8 and a ninth width W9. The first width W1 may be greater than the fourth width W4, the second width W2 may be greater than the fifth width W5, and the third width W3 may be the same as the sixth width W6. In addition, the fourth width W4 may be the same as the seventh width W7, the fifth width W5 may be the same as the eighth width W8, and the sixth width W6 may be the same as the ninth width W9.

Hereinafter, the stacked structure of the display device 1 based on some embodiments will be described in detail.

The display device 1 based on an embodiment may include a substrate 2, an insulating layer 3, a first electrode 4, a first protective layer PS1, a second protective layer PS2, a common light emitting layer 5, a second electrode 6, a capping layer 7, an encapsulating layer 8, and a color filter layer 9.

The substrate 2 may be a plastic film, a glass substrate, or a semiconductor substrate such as silicon.

The substrate 2 may include a transparent material or an opaque material. In some implementations, a first sub-pixel 21, a second sub-pixel 22 and a third sub-pixel 23 may be disposed on the substrate 2. The first sub-pixel 21 may emit red light R, the second sub-pixel 22 may emit blue light B, and the third sub-pixel 23 may emit green light G.

The display device 1 based on an embodiment may be configured in a top emission manner in which the emitted light is emitted upward. Accordingly, not only a transparent material but also an opaque material may be used as the material of the substrate 100. Color filters 91, 92 and 93 may be disposed on upper sides of the first to third sub-pixels 21, 22 and 23 from which the light is emitted, respectively, to transmit the light of the colors mentioned above.

The insulating layer 3 may be formed on the substrate 2. The insulating layer 3 may include a plurality of insulating layers 3a, 3b, 3c, 3d, 3e, 3f and 3g.

A first insulating layer 3a may be disposed on the substrate 2. Circuit elements such as a plurality of thin film transistors 31, 32 and 33, various signal wires and capacitors may be provided for each of the sub-pixels 21, 22 and 23. The signal wires may include a gate line, a data line, a power line and a referenced line. The thin film transistors 31, 32 and 32 may include a switching thin film transistor, a driving thin film transistor, and a sensing thin film transistor. Each of the sub-pixels 21, 22 may be defined by the crossing structure of the gate lines and the data lines.

The switching thin film transistor may be configured to supply the data voltage from the data line when the switching thin film transistor is switched based on a gate signal supplied to the gate line.

The driving thin film transistor may be configured to generate data current from the power switched based on the data voltage supplied from the switching thin film transistor and supplied from the power line, and supply the generated data current to the first electrode 4.

The sensing thin film transistor may be configured to sense the threshold voltage deviation of the driving thin film transistor, which causes image quality degradation, and it may supply, to the referenced line, the current of the driving thin film transistor in response to a sensing control signal, which is supplied from the gate line or a separate sensing line.

The capacitor may be configured to maintain the data voltage supplied to the driving thin film transistor for one frame, and it may be connected to the gate terminal and the source terminal of the driving thin film transistor, respectively.

The first transistor 31, the second transistor 32 and the third transistor 33 may be disposed in the first insulating layer 3a for each of the sub-pixels 21, 22 and 23. The first transistor 31 may be connected to the first electrode 4 disposed on the first sub-pixel 21, and configured to apply a driving voltage for emitting the light of color corresponding to the first sub-pixel 21.

The second transistor 32 may be connected to the first electrode 4 disposed on the second sub-pixel 22, and configured to apply a driving voltage for emitting the light of color corresponding to the second sub-pixel 22.

The third transistor 33 may be connected to the first electrode 4 disposed on the third sub-pixel 23, and configured to apply a driving voltage for emitting the light of color corresponding to the third sub-pixel 23.

Each of the first sub-pixel 21, the second sub-pixel 22 and the third sub-pixel 23 may supply a predetermined current to the light emitting layer based on the data voltage of the data line, when a gate signal is input from the gate line using each of the transistors 31, 32 and 33. As a result, the light emitting layer of each of the first sub-pixel 21, the second sub-pixel 22 and the third sub-pixel 23 may emit light with a predetermined brightness based on a predetermined current.

The first insulating layer 3a may protect the transistors 31, 32 and 33. The first insulating layer 3a may include an inorganic insulating material, but the disclosed technology is not limited thereto. The first insulating layer 3a may include an organic insulating material. The transistors 31, 32 and 33 may be provided within the first insulating layer 3a. For example, the first insulating layer 3a may include an inorganic material such as silicon nitride SiNx, silicon oxide SiOx, or aluminum oxide Al2O3, but the disclosed technology is not limited thereto.

The second insulating layer 2c may be disposed on the first insulating layer 2a. For example, the second insulating layer 2c may include an inorganic material such as silicon nitride SiNx, silicon oxide SiOx, or aluminum oxide Al2O3, but the disclosed technology is not limited thereto.

The third insulating layer 3c may be disposed on the second insulating layer 2b. For example, the third insulating layer 3c may include an inorganic material such as silicon nitride SiNx, silicon oxide SiOx, or aluminum oxide Al2O3, but the disclosed technology is not limited thereto.

The fourth insulating layer 3d may be disposed on the third insulating layer 3c. For example, the fourth insulating layer 3d may include an inorganic material such as silicon nitride SiNx, silicon oxide SiOx, or aluminum oxide Al2O3, but the disclosed technology is not limited thereto.

The fifth insulating layer 3e may be disposed on the fourth insulating layer 3d. For example, the fifth insulating layer 3e may include an inorganic material such as silicon nitride SiNx, silicon oxide SiOx, or aluminum oxide Al2O3, but the disclosed technology is not limited thereto.

In the non-light emitting areas NEA1, NEA2 and NEA3, a contact hole CT may penetrate the first to fifth insulating layers 3a to 3e in the thickness direction, and may be electrically connected to the transistors 31, 32 and 33 of each sub-pixel 21, 22 and 23. The contact hole CT may include tungsten, but the disclosed technology is not limited thereto.

The first to fifth insulating layers 3a to 3e may be etched in the first light emitting area EA1. A first reflective electrode 42a may be disposed in the area in which the first to fifth insulating layers 3a to 3e of the first light emitting are EA1 are etched. The first reflective electrode 42a may be in contact with an upper surface of the second insulating layer 3b, and may be in direct contact with lateral surfaces of the third to fifth insulating layers 3c to 3e.

The fourth and fifth insulating layers 3d and 3e may be etched in the second light emitting area EA2. The second reflective electrode 42b may be disposed in the area where the fourth and fifth insulating layer 3d and 3e are etched in the second light emitting area EA2. The second reflective electrode 42b may be in contact with an upper surface of the fourth insulating layer 3d, and it may be in direct contact with a lateral surface of the fifth insulating layer 3e.

The third reflective electrode 42c may be disposed on the fifth insulating layer 3e in the third light emitting area EA3. A protective electrode PM may be disposed between the third reflective electrode 42c and the fifth insulating layer 3e. In the third light emitting area EA3, the protective electrode PM and the third reflective electrode 42c may have the same width, and a lateral surface of the protective electrode PM and a lateral surface of the third reflective electrode 42c may be aligned.

In some implementations, connection electrodes CEa, CEb and CE3 may be disposed on each of the contact holes CT in the non-light emitting areas NEA1, NEA2 and NEA3. The protective electrode PM may be disposed between the connection electrodes CEa, CEb and CEb and the contact hole CT. In one example, the protective electrode PM may include aluminum Al, but the disclosed technology is not limited thereto. In the non-light emitting areas NEA1, NEA2 and NEA3, each corresponding protective electrode PM and each corresponding connection electrode CEa, CEb and CEc may have the same width, and a lateral surface of the protective electrode PM and a lateral surface of the connection electrode CEa, CEb and CEc may be aligned.

In some implementations, each of the reflective electrodes 42a, 42b and 42c may be disposed on the same layer, and may contain the same material. The surface heights of the reflective electrodes 42a, 42b and 42c may be different from each other. For example, the surface height of the third reflective electrode 42c may be the highest, followed by the surface height of the second reflective electrode 42b, and the surface height of the first reflective electrode 42a may be the lowest. The reflective electrodes 42a, 42b and 42c may reflect the light among light rays emitted from the common light emitting layer 5 of each sub-pixel 21, 22 and 23 toward the reflective electrode 42, toward the second electrode 6 or the encapsulating layer 8. In addition, the reflective electrode 42 may be configured to implement micro-cavity characteristics through reflection and re-reflection with the second electrode 6. To this end, the reflective electrode 42 may include a reflective material for reflecting light. For example, the reflective material may include metal, but the disclosed technology is not limited thereto. The reflective material may include any other materials capable of reflecting light. For example, the reflective material may contain titanium Ti/Aluminum al, but the disclosed technology is not limited thereto.

The anode electrodes 41a, 41b and 41c may be patterned for each of the first to third sub-pixels 21, 22 and 23. The anode electrodes 41a, 41b and 41c may be connected to the driving thin film transistor provided on the insulating layer 3. For example, the anode electrodes 41a, 41b and 41c may be electrically connected to the transistors 31, 32 and 33 through the above-noted contact hole CT.

A first anode electrode 41a may be electrically connected to a first transistor 31 through the protective electrode PM and the contact hole Ct, a second anode electrode 41b may be electrically connected to a second transistor 32 through the protective electrode PM and the contact hole CT, and a third anode electrode 41c may be electrically connected to a third transistor 33 through the protective electrode PM and the contact hole CT.

The display device 1 based on an embodiment may be formed in a top emitting manner, and for this purpose, the reflective electrode 42 may be provided to reflect the light emitted from the common light emitting layer 5 upward.

The reflective electrode 42 may reflect light rays emitted toward the reflective electrode 42 among light rays emitted from the common light emitting layer 5, toward the second electrode 6 or the encapsulating layer 8. In addition, the reflective electrode 42 may be configured to implement the micro-cavity characteristics through reflection and re-reflection with the second electrode 6. To this end, the reflective electrode 42 may include a reflective material for reflecting light.

Since the reflective electrode 42 is arranged at a relatively lower position than the common light emitting layer 5, the light emitted from the common light emitting layer 5 may be reflected upward. Here, the upper direction represents the direction in which the user can perceive light, and for example, it may represent the direction where the encapsulating layer 8 or a color filter layer 9 is disposed. Accordingly, the first sub-pixel 21, the second sub-pixel 22 and the third sub-pixel 23 may improve the light efficiency compared to when there is no reflective electrode 42, and the user can perceive a high-brightness or clear image through the improved light efficiency.

As described above, the display device 1 may include the reflective electrode 42 such that light extraction efficiency can be improved using the micro-cavity characteristics. The reflective electrode 42 may include a first reflective electrode 42a, a second reflective electrode 42b and a third reflective electrode 42c.

The distance between the first reflective electrode 42a and the first anode electrode 41a may be greater than the distance between the second reflective electrode 42b and the second anode electrode 41b. The distance between the second reflective electrode 42b and the second anode electrode 41b may be greater than the distance between the third reflective electrode 42c and the third anode electrode 41c.

The second electrodes 6 in the light emitting areas EA1, EA2 and EA3 of the respective sub-pixels 21, 22 and 23 may be positioned on the same line. Accordingly, the distance relationship between the respective reflective electrodes 42a, 42b and 42c and the first electrode 4 in each sub-pixel 21, 22 and 23 may be the same as the distance relationship between the respective reflective electrodes 42a, 42b and 42c and the second electrode 6. The anode electrode 41 may include a first anode electrode 41a, a second anode electrode 41b and a third anode electrode 41c that are disposed in the sub-pixels 21, 22 and 23, respectively.

By forming the reflective electrodes 42a, 42b and 42c to have various distances (or resonance distances) from the second electrode 6, the light extraction efficiency of different colors can be improved through reflection and re-reflection between the reflective electrodes 42a, 42b and 42b and the second electrode 6 based on the distance. Accordingly, the light extraction efficiency of red light may be improved in the first sub-pixel 21, the light extraction of green light may be improved in the second sub-pixel 22, and the light extraction of blue light may be improved in the third sub-pixel 23.

The connection electrodes CEa, CEb and CEc may be disposed in the light emitting areas EA1, EA2 and EA3 of each sub-pixel 21, 22 and 23. The connection electrodes CEa, CEb and CEc may be disposed on the same layer as the reflective electrodes 42a, 42b and 42c, respectively, and may be formed through the same process.

The anode electrodes 41a, 41b and 41c may be disposed on the reflective electrodes 42a, 42b and 42c, respectively. The anode electrodes 41a, 41b and 41c may be configured to supply hole to the common light emitting layer 5. The anode electrodes 41a, 41b and 41c may be transparent so that light reflected from the reflective electrodes 42a, 42b and 42c can travel upward. The anode electrode 41a, 41b and 41c may include a transparent material, but the disclosed technology is not limited thereto. It may be formed of a thin film that includes a metal material capable of transmitting light. For example, the anode electrode 41a, 41b and 41b may include titanium nitride TiN, but the disclosed technology is not limited thereto. The anode electrode 41a, 41b and 42c may be formed of a super thin film so that the light reflected from the reflective electrode 42a, 42b and 42c can travel upward. For example, the thickness of the anode electrode 41a, 41b and 41c may be about 5 nm or less. for another example, the thickness of the anode electrode 41a, 41b and 41c may be about 3 nm or less, but the disclosed technology is not limited thereto.

The anode electrodes 41a, 41b and 41c may be disposed in each of the first to third sub-pixels 21, 22 and 23 so as to have almost the same height from an upper surface of the reflective electrode 42a, 42b and 42c or the insulating layer 3.

In the first sub-pixel 21, the width W1 of the first reflective electrode may be greater than the width W7 of the first anode electrode 41a. In the second sub-pixel 22, the width W2 of the second reflective electrode 42b may be greater than the width W8 of the second anode electrode 41b. In the third sub-pixel 23, the width W3 of the third reflective electrode 42c may be the same as the width W9 of the third anode electrode 41c.

The first reflective electrode 42a and the second reflective electrode 42b may be formed in a basket shape. That is, each reflective electrode 42a, 42b and 42c may include a bottom portion that is in contact with the second insulating layer 3b in the case of a lower insulating layer (e.g., the second insulating layer 3b in the case of the first reflective layer 42a and the fourth insulating layer 3d in the case of the second reflective electrode 42b), and a lateral wall portion that is in contact with the insulating layer exposed after etched (e.g., the third to fifth insulating layers 3C to 3e in the case of the first reflective electrode 42a and the fifth insulating layer 3e in the case of the second reflective electrode 42b).

In each sub-pixel 21, 22 and 23, the first electrode 4 may be disposed in the light emitting areas EA1, EA2 and EA3 and in some areas of the non-light emitting areas NEA1, NEA2 and NEA3. However, the first electrode 4 disposed in each sub-pixel 21, 22 and 23 may be physically separated from the first electrode 4 disposed in adjacent sub-pixels 21, 22 and 23. In the non-light emitting areas NEA1, NEA2 and NEA3, the anode electrodes 41a, 41b and 41c may be in direct contact with the connection electrodes CEa, CEb and CEc, respectively. In the non-light emitting areas NEA1, NEA2 and NEA3, the width of each anode electrode 41a, 41b and 41c may be the same as the width of each connection electrode CEa, CEb and CEc correspondingly provided thereunder. A lateral surface of each anode electrode 41a, 41b and 41c may be aligned with a lateral surface of each connection electrode CEa, CEb and CEc correspondingly provided thereunder.

A sixth insulating layer and a seventh insulating layer 3f and 3g may be disposed between the reflective electrodes 42a and 42b and the anode electrodes 41a and 41b. The sixth insulating layer 3f may be disposed between the reflective electrodes 42a and 42b and the anode electrodes 41a and 41b, and may be in direct contact with the lower portions and lateral wall portions of the reflective electrodes 42a and 42b. The sevenths insulating layer 3g may be disposed between the sixth insulating layer 3f and the anode electrodes 41a and 41b. The sixth insulating layer 3f may be made of an inorganic material such as silicon nitride SiNx, silicon oxide SiOx, or aluminum oxide Al2O3, but the disclosed technology is not limited thereto. The seventh insulating layer 3g may include an inorganic material such as silicon nitride SiNx, silicon oxide SiOx, or aluminum oxide Al2O3, but the disclosed technology is not limited thereto.

The surface of the seventh insulating layer 3g may be protruded upward (in a direction DR3) more than the surfaces of the adjacent reflective electrodes 42a and 42b in the first and second sub-pixels 42a and 42b and the surface of the sixth insulating layer 3f. The thickness t1 of the seventh insulating layer 3g in the first sub-pixel 21 may be greater than the thickness t2 of the seventh insulating layer 3g in the second sub-pixel 22.

The anode electrodes 41a and 41b may be disposed directly on an upper surface of the seventh insulating layer 3g in the first and second sub-pixels 21 and 22. The widths W7 and W8 of the anode electrodes 41a and 41b may be the same as the width of the seventh insulating layer 3g corresponding thereto.

The protective layers PS1 and PS2 may be disposed on the anode electrodes 41a, 41b and 41c. Each protective layer PS1 and PS2 may include inorganic materials such as silicon nitride SiNx, silicon oxide SiOx, or aluminum oxide Al2O3, but the disclosed technology is not limited thereto.

In the light emitting areas EA1, EA2 and EA3, the protective layer PS1 and PS2 may define the light emitting areas EA1, EA2 and EA3 by exposing the upper surfaces of the anode electrodes 41a, 41b and 41c. in the first and second sub-pixels 21 and 22, the first protective PS1 may be in direct contact with the surfaces of the reflective electrodes 42a and 42b and the later surface of the seventh insulating layer 3g protruded upward DR3 more than the surfaces of the sixth insulating layer 3f. In contrast, in the non-light emitting areas NEA1, NEA2 and NEA3, the protective layers PS1 and PS2 may cover all the upper surfaces of the connection electrodes CEa, CEb and CEc.

The common light emitting layer 5 may be formed on the anode electrodes 41a, 41b and 41c and the protective layers PS1 and PS2. The common light emitting layer 5 may also be formed on the second protective layer PS2 disposed between the sub-pixels 21, 22 and 23. The common light emitting layer 5 may be in contact with the upper surfaces of the anode electrodes 41a, 41b and 41c. The common light emitting layer 5 may be in direct contact with the lateral surface of the first protective layer PS1 and the lateral and upper surface of the second protective layer PS2.

An organic light emitting display according to one embodiment may include a first electrode 4 (ANO), a second electrode 6 (CAT), and a common light emitting layer 5 disposed between the first electrode 4 and the second electrode 6.

The common light emitting layer 5 may be configured to emit white light W. For this purpose, the common light emitting layer 5 may include a plurality of stacks that emit light of different colors. Specifically, the common light emitting layer 5 may include a first stack, a second stack, a charge generation layer CGL provided between the first stack and the second stack. The second electrode.

The second electrode 6 may be formed in the common light emitting layer 5. The second electrode 6 may function as a cathode of the display 1. The second electrode 6 may be formed in and also between the sub-pixels 21, 22 and 23, similar to the common light emitting layer 5.

Meanwhile, since it is formed on the upper surface of the common light emitting layer 5, the second electrode 6 may be formed along a profile of the common light emitting layer 5. The common light emitting layer 5 may be formed along the profile of the first electrode 4 in the light emitting area, such that the second electrode 6 may be formed along the profile of the first electrode 4. In addition, a capping layer 7 formed on the second electrode 6 may also be formed along the profile of the second electrode 6.

The capping layer 7 may include an inorganic insulating material, but the disclosed technology is not limited thereto. The capping layer 7 may be disposed on the second electrode 6 to protect the inorganic light emitting display OLED.

The encapsulating layer 8 may be formed on the second electrode layer 6 and configured to prevent external moisture from penetrating into the common light emitting layer 5. In some implementations, the encapsulating layer 8 may include an inorganic insulating material and formed of a structure in which an inorganic insulating material and an organic insulating material are alternately disposed, but the disclosed technology is not limited thereto.

The color filter layer 9 may be formed on the encapsulating layer 8. The color filter layer 9 may include a first color filter 91 provided in the first sub-pixel 21 as a red R filter, a second color filter 92 provided in the second sub-pixel 22 as a green G filter, and a third color filter 93 provided in the third sub-pixel 23 as a blue B filter, but the disclosed technology is not limited thereto.

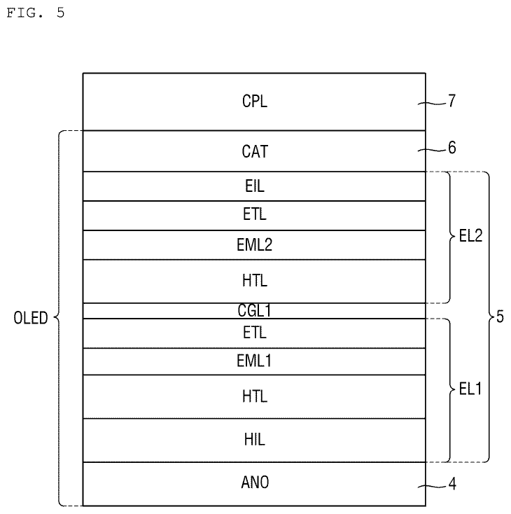

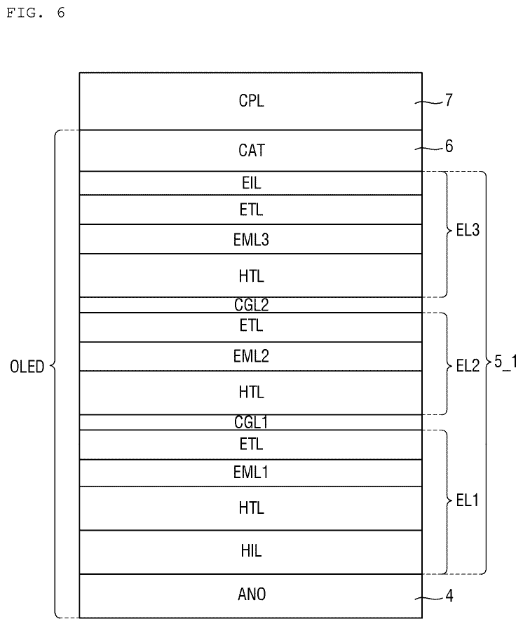

FIG. 5 is a cross-sectional view illustrating an organic light emitting display according to an example of FIG. 2. FIG. 6 is a cross-sectional view illustrating an organic light emitting display according to a modified example of FIG. 2.

Referring to FIGS. 1 to 5, the common light emitting layer 5 may include a first stack EL1, a second stack EL2 and a first charge generation layer CGL 1 that provided on the first electrode 4.

The first stack EL1 may be disposed on the first electrode 4, and may have the structure in which a hole injecting layer HIL, a hole transporting layer HTL, a blue B emitting layer EM1 are sequentially disposed.

The first stack EL1 may be disposed between the first sub-pixel 21 and the second sub-pixel 22, and also between the second sub-pixel 22 and the third sub-pixel 23.

The first charge generation layer CGL1 may be configured to supply charge to the first stack EL1 and the second stack EL2. The first charge generation layer CGL1 may include an N-type charge generation layer configured to supply electrons to the first stack EL1 and a P-type charge generation layer configured to supply holes to the second stack EL2. The N-type charge generation layer may include a metal material as dopant.

The second stack EL2 may be disposed on the first stack EL2, and may be formed in the structure in which a hole transporting layer HTL, a yellow green YG emitting layer EML2, an electron transporting layer ETL, and an electron injecting layer EIL are sequentially disposed.

The second stack EL2 may be disposed between the first sub-pixel 21 and the second sub-pixel 22, and also between the second sub-pixel 22 and the third sub-pixel 23.

As a result, the common light emitting layer 5 may be provided as a common layer over the first to third sub-pixels 21, 22 and 23, as shown in FIGS. 3 and 4.

As shown in FIG. 6, a common light emitting layer 5_1 of an organic light emitting display OLED based on an embodiment may include a first stack EL1, a second stack EL2 and a third stack EL3 disposed on the first electrode 4, a first charge generation layer CGL1 disposed between the first stack EL1 and the second stack EL2, and a second charge generation layer CGL2 disposed between the second stack EL2 and the third stack EL3.

The first stack EL1 may be provided on the first electrode 4, and may be formed in the structure in which a hole injecting layer HIL, a hole transporting layer HTL, a blue B emitting layer EML1 and an electron transporting layer ETL are sequentially disposed.

The first stack EL1 may be disposed between the first sub-pixel 221 and the second sub-pixel 22 and between the second sub-pixel 22 and the third sub-pixel 23, that is, on the protective layer PS1 and PS2.

The first charge generation layer CGL1 may be configured to supply charge to the first stack EL1 and the second stack EL2. The first charge generation layer CGL1 may include an N-type charge generation layer configured to supply electrons to the first stack EL1 and a P-type charge generation layer configured to supply holes to the second stack EL2. The N-type charge generation layer may include a metal material as dopant.

The second stack EL2 may be disposed on the first stack EL2, and may be formed in the structure in which a hole transporting layer HTL, a green G emitting layer EML2 and an electron transporting layer ETL are sequentially disposed.

The second stack EL2 may be disposed between the first sub-pixel 21 and the second sub-pixel 22 and between the second sub-pixel 22 and the third sub-pixel 23, e.g., on a bank BK.

The second charge generation layer CGL2 may be configured to supply charge to the second stack EL2 and the third stack EL3. The second charge generation layer CGL2 may include a N-type charge generation layer for supplying electrons to the second stack EL2, and a P-type charge generation layer for supplying holes to the third stack EL3. The N-type charge generation layer may contain a metal material as a dopant.

The third stack EL3 may be provided on the second stack EL2, and may be formed in the structure in which a hole transporting layer HTL, a red R emitting layer EML3, an electron transporting layer ETL, and an electron injecting layer EIL are sequentially disposed.

As shown in FIGS. 1 to 6, the charge generation layer CGL1 and CGL2 may be disposed between the first sub-pixel 21 and the sub-pixel 22 and between the second sub-pixel 22 and the third sub-pixel 23. In some implementations, in the display device based on an embodiment, the common light emitting layer 5 may be disposed even between each two of the sub-pixels 21, 22 and 23. As a result, when one sub-pixel emits light, a lateral leakage current might occur to the adjacent sub-pixels 21, 22 and 23 through the charge generation layer CGL1 and CGL2. To this end, a trench TRP may be formed between the sub-pixels 21, 22 and 23. The trench TRP may be the area formed by cutting the seventh insulating layer 3g at the boundary of each sub-pixel 21, 22 and 23. The formation length of the common light emitting layer 5 at the boundary of the sub-pixels 21, 22 and 23 can be increased through the trench TRP, thereby lengthening the current path. Accordingly, the occurrence of lateral leakage current can be prevented. Furthermore, the common light emitting layer 5 can be separated from the trench TRP, thereby preventing lateral leakage current in advance.

Referring to FIGS. 2 to 4 again, the second electrode 6 may be formed on the common light emitting layer 5, the encapsulating layer 8 may be formed on the second electrode 6, and the color filter layer 9 may be formed on the encapsulating layer 8.

Although not shown in the drawings, the first to third color filters 91, 92 and 93 to prevent color mixing between the sub-pixels.

As described above, each of the first reflective electrode 42a and the second reflective electrode 42b may have a basket shape. That is, each reflective electrode 42a and 42b may include a lower portion that is in contact with the insulating layer disposed thereunder (e.g., the second insulating layer 3b in the case of the first reflective electrode 42a and the fourth insulating layer 3d in case of the second reflective electrode 42b), and a lateral wall portion that is in contact with the insulating layer exposed after etched (e.g., the third to fifth insulating layer 3c to 3e in the case of the first reflective electrode 42a).

A first light ray L1 or a second light ray L2 may be directed from the common light emitting layer 5 downward. The first light L1 may be reflected from the lateral wall portions and the lower portion of the reflective electrodes 42a and 42b sequentially, and then enter the second electrode 6 again. In other words, in the display device 1 based on an embodiment, each of the first and second reflective electrodes 42a and 42b may be formed in the basket shape, thereby further including the lateral wall portions. Accordingly, the light traveling to areas other than the lower portion may be re-reflected (i.e., collected or condensed) upward again, thereby improving light efficiency.

The second light L2 may be reflected from the lower portion and the lateral wall portions of the reflective electrodes 42a and 42b sequentially, and then enter the second electrode 6. In other words, in the display device 1 based on an embodiment, each of the first and second reflective electrodes 42a and 42b may be formed in the basket shape, thereby further including the lateral wall portions and preventing the light reflected from the lower portion from entering into the adjacent sub-pixels 21, 22 and 23. As a result, light mixing between adjacent sub-pixels 21, 22 and 23 can be prevented.

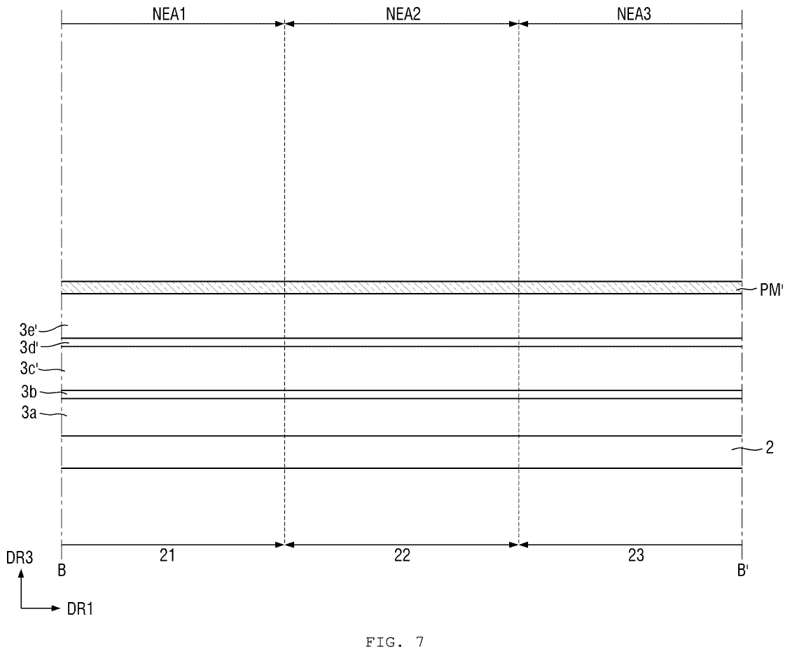

FIGS. 7 to 29 are cross-sectional views illustrating process steps of a method for manufacturing a display device based on an embodiment.

Hereinafter, a method for manufacturing the display device 1 according to one embodiment will be described. While describing the method for manufacturing the display device 1, repeated description of the elements shown in FIGS. 1 to 4 will be omitted.

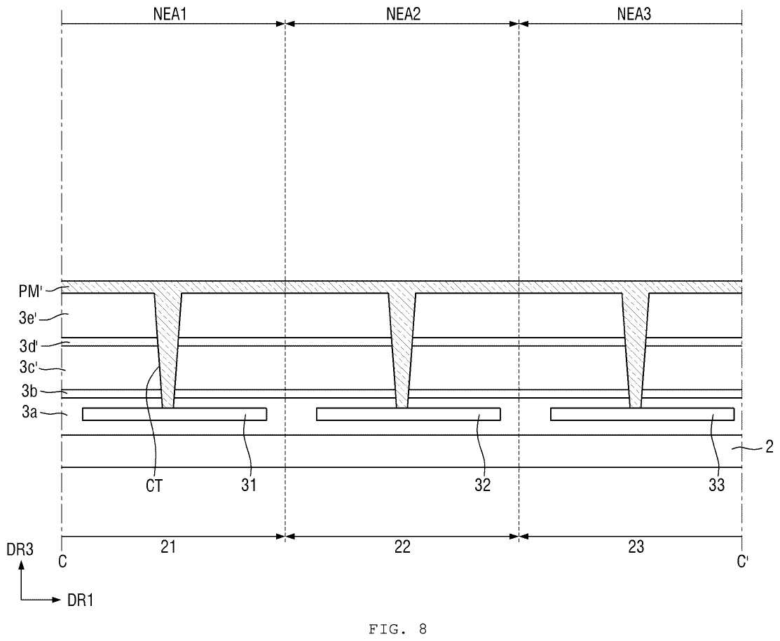

Referring to FIGS. 7 and 8, insulating layers 3a, 3b, 3c′, 3d and 3e′ and a protective electrode layer PM′ may be formed on a substrate 2.

The substrate 2 may include a transparent material or an opaque material. In some implementations, a first sub-pixel 21, a second sub-pixel 22 and a third sub-pixel 23 may be disposed on the substrate 2. The first sub-pixel 21 may emit red light R, the second sub-pixel 22 may emit blue light B, and the third sub-pixel 23 may emit green light G.

The insulating layers 3a, 3b, 3c′, 3d′ and 3e may be disposed over the sub-pixels 21, 22 and 23. A first insulating layer 3a may be disposed on the substrate 2. In the first insulating layer 3a, circuit elements including a plurality of thin film transistors 31, 32 and 33, various signal wires and capacitors may be provided for each sub-pixel 21, 22 and 23. The signal wires may include a gate line, a data line, a power line and a referenced line. The thin film transistors 31, 32 and 33 may include a switching thin film transistor, a driving thin film transistor and a sensing thin film transistor. Each of the sub-pixels 21, 22 and 23 may be defined by the crossing structure of the gate lines and data lines. The first insulating layer 3a may protect the transistors 31, 32 and 33. The first insulating layer 3a may include an inorganic insulating material, but the disclosed technology is not limited thereto. In some implementations, the first insulating layer 3a may include an organic insulating material.

The second insulating layer 3b may include an inorganic material such as silicon nitride SiNx, silicon oxide SiOx, or aluminum oxide Al2O3, but the disclosed technology is not limited thereto.

The third insulating layer 3c′ may include an inorganic material such as silicon nitride SiNx, silicon oxide SiOx, or aluminum oxide Al2O3, but the disclosed technology is not limited thereto.

The fourth insulating layer 3d′ may include an inorganic material such as silicon nitride SiNx, silicon oxide SiOx, or aluminum oxide Al2O3, but the disclosed technology is not limited thereto.

The fifth insulating layer 3e′ may include an inorganic material such as silicon nitride SiNx, silicon oxide SiOx, or aluminum oxide Al2O3, but disclosed technology is not limited thereto.

In the non-light emitting areas NEA1, NEA2 and NEA3, the first to fifth insulating layers 3a to 3e′ may be penetrated, and contact hole CT may be disposed in the penetrated first to fifth insulating layers 3a to 3e′.

The protective electrode layer PM′ may be disposed aver the sub-pixels 21, 22 and 23. The protective electrode layer PM′ may contain aluminum Al, but the disclosed technology is not limited thereto.

In the non-light emitting areas NEA1, NEA2 and NEA3, the protective electrode layer PM′ may be electrically connected to the contact hole CT.

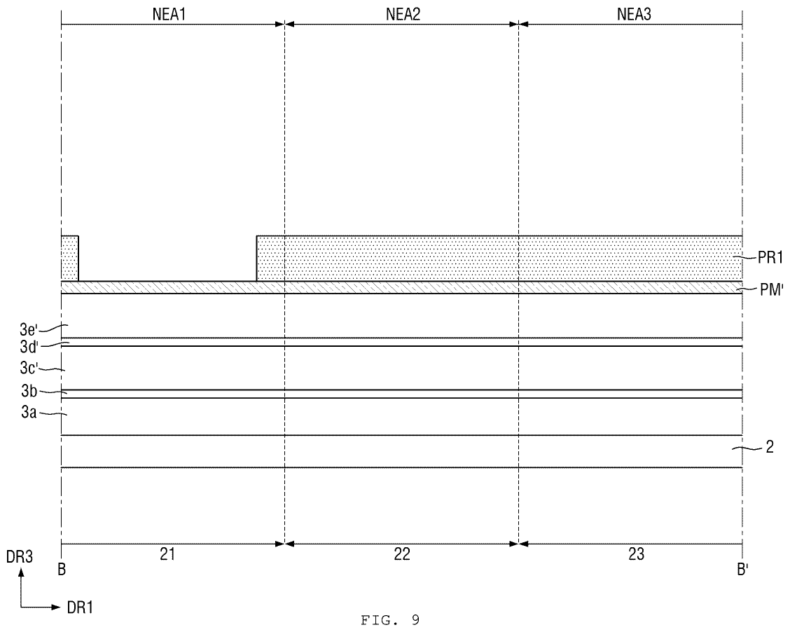

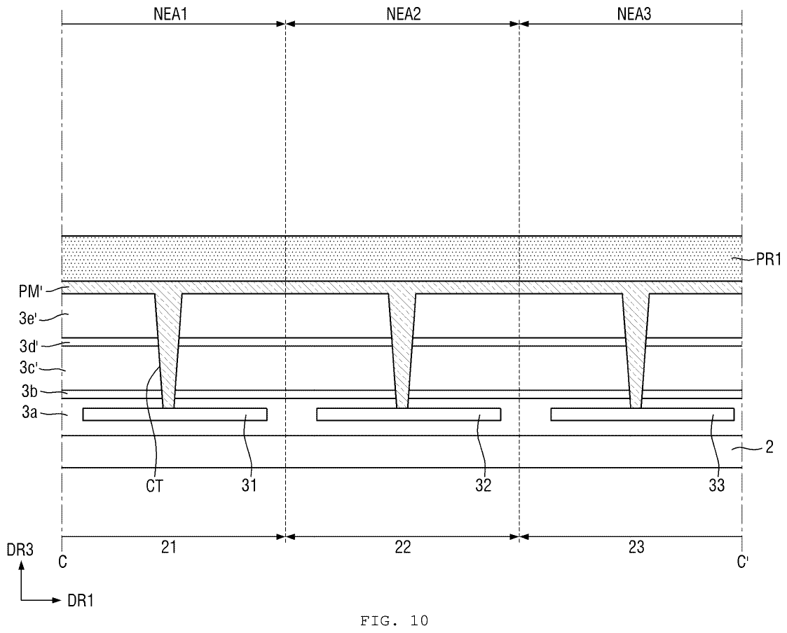

Referring to FIGS. 9 and 10, a first photoresist PR1 is formed. The first photoresist PR1 may be formed over the entire surface except the area where the first reflective electrode 42a of FIG. 3 is to be formed.

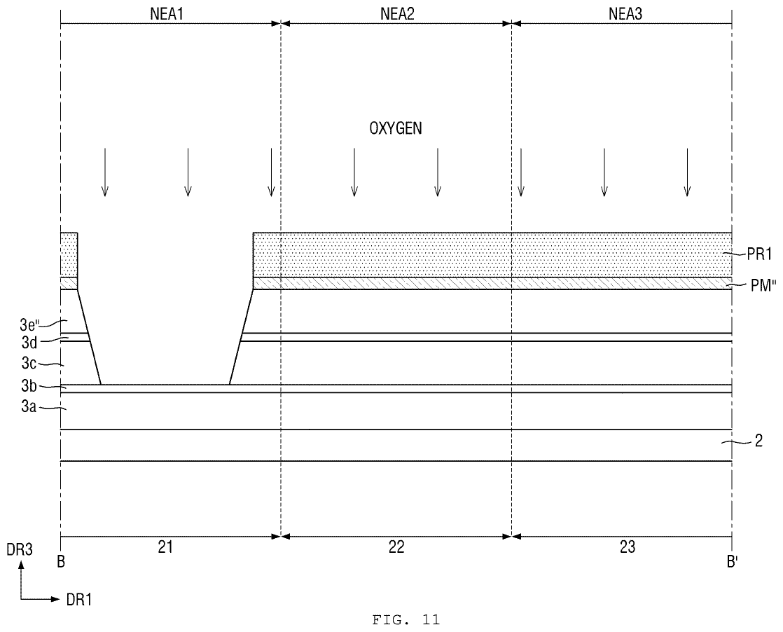

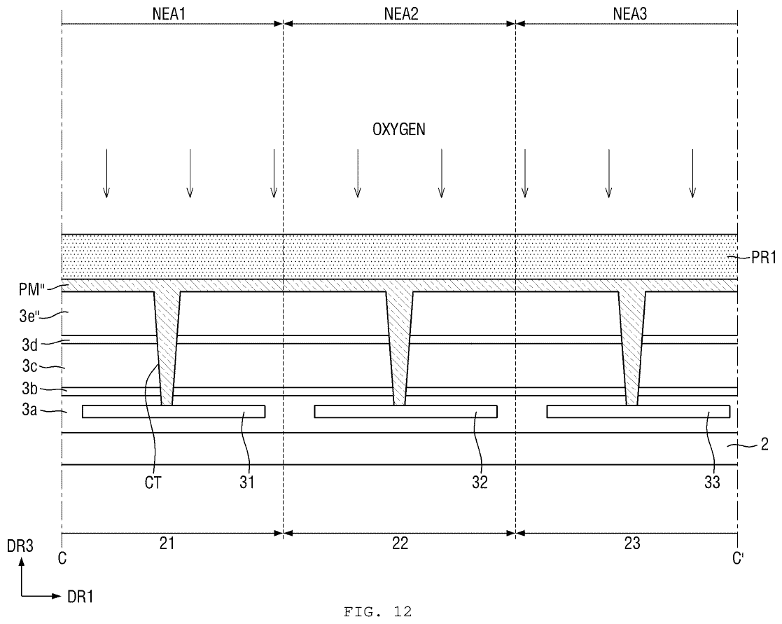

Referring to FIGS. 11 and 12, the protective electrode layer PM″ of the first sub-pixel 21 and the third to fifth insulating layers 3c, 3d and 3e″ may be formed by using the first photoresist PR1. The area exposed by the protective electrode layer PM″ and of the first photoresist PR1 of the third to fifth insulating layers 3c, 3d and 3e″ may be removed through dry-etching. Then, the first photoresist PR1 may be removed. The removal of the first photoresist PR1 may use an ashing process. The ashing process may include an oxygen plasma process. Specifically, when the first photoresistor PR1 is exposed to oxygen OXYGEN in the form of plasma, the first photoresist PR1 may be removed. The contact hole CI may be disposed in the non-light emitting areas NEA1, NEA2 and Nea3, and unless the protective electrode layer PM″ is provided, the contact hole CT might be exposed to oxygen during the ashing process and oxidized. However, by performing the method for manufacturing the display device 1 based on an embodiment, the protective electrode layer PM″ may cover the contact hole CT in the ashing process, to prevent the oxidization of the contact hole CT.

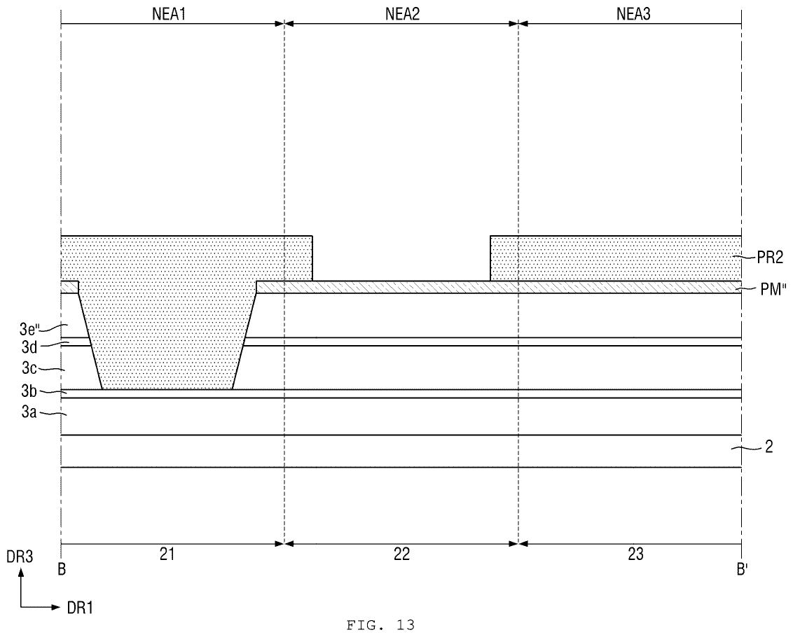

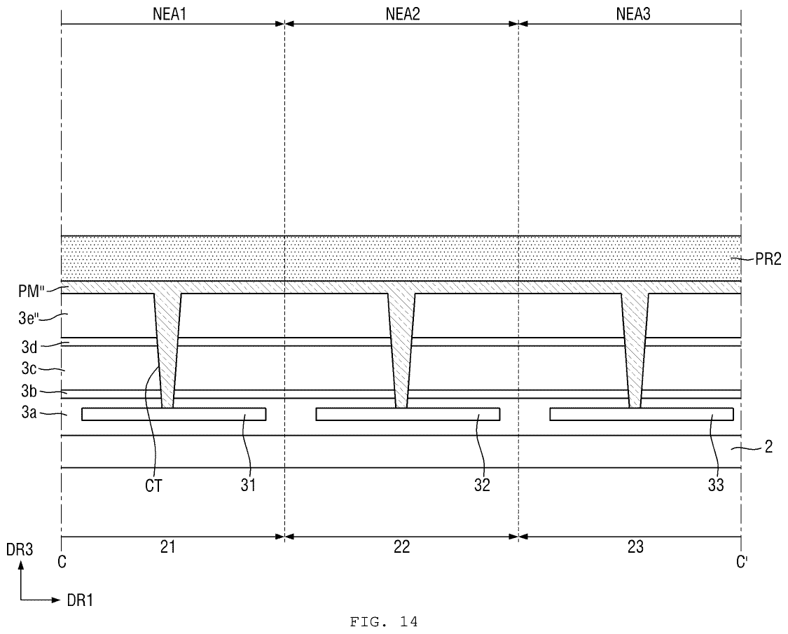

Referring to FIGS. 13 and 14, a second photoresist PR2 may be formed. The second photoresist PR2 may be formed over the entire surface except the area where the second reflective electrode 42b of FIG. 3 is to be formed.

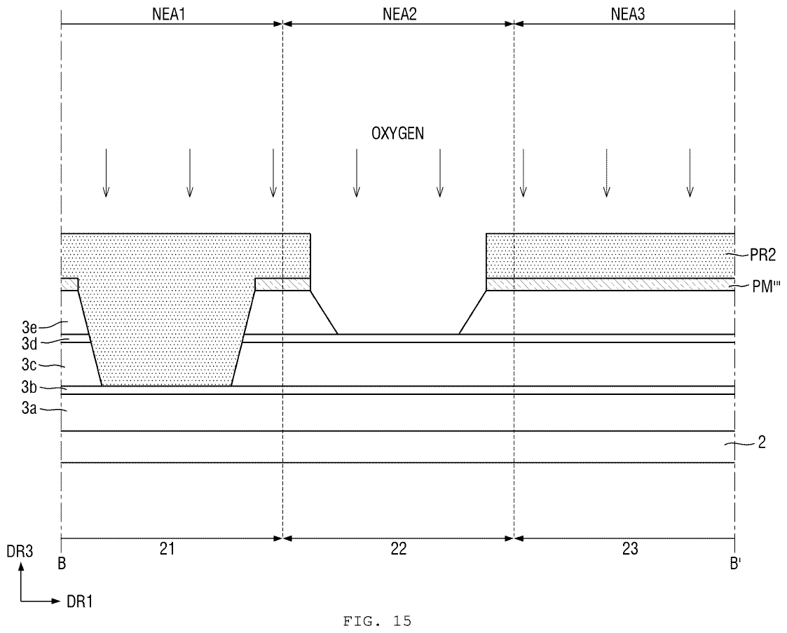

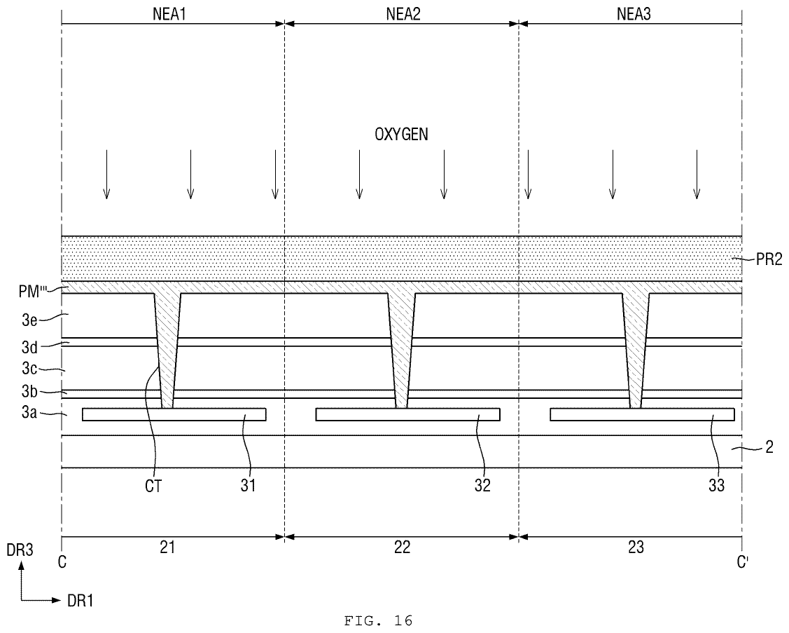

Referring to FIGS. 15 and 16, the protective electrode layer PM″′ of the second sub-pixel 22 and the fifth insulating layer 3e″ may be formed by using the second photoresist PR2. The area exposed by the protective electrode layer PM″′ and the second photoresist PR2 of the fifth insulating layers 3e may be removed through dry-etching. Then, the second photoresist PR2 may be removed. The removal of the second photoresist PR2 may use an ashing process. The ashing process may include an oxygen plasma process.

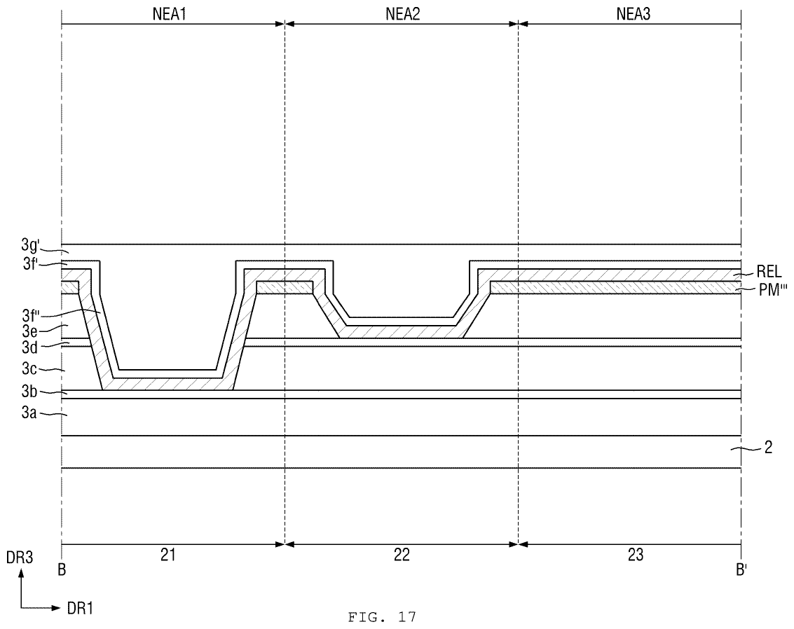

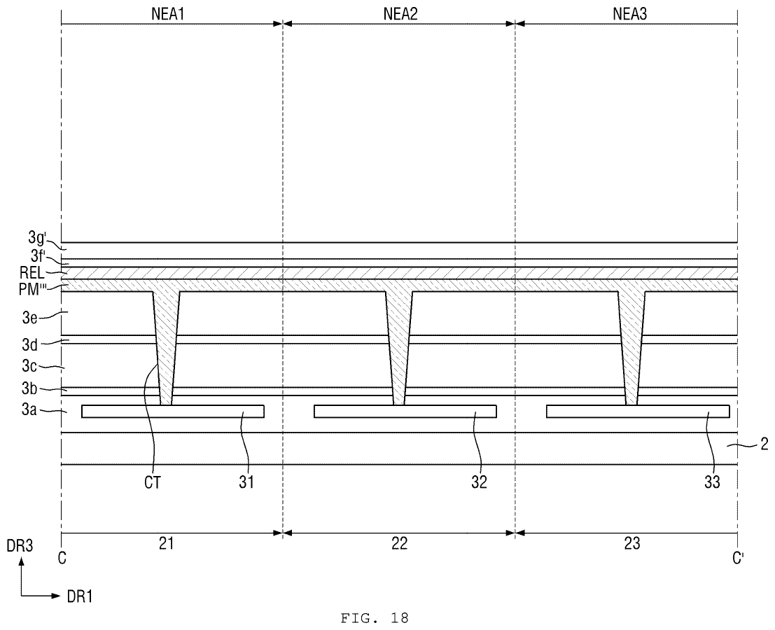

Referring to FIGS. 17 and 18, the protective electrode layer RIL, the sixth insulating layer 3f′ and the seventh insulating layer 3g′ may be sequentially disposed on the protective electrode layer PM′″ and the insulating layers 3b to 3e. Since the protective electrode layer PM″′ is disposed in the non-light emitting areas NEA1, NEA2 and NEA3 and the third sub-pixel 23, the reflective electrode layer REL may be disposed directly on an upper surface of the protective electrode layer REL in the non-light emitting areas NEA1, Nea2 and NEA3 and the third sub-pixel 23, and the reflective electrode layer REL may be in direct contact with a lateral surface of the protective electrode layer PM′″ disposed in the non-light emitting areas NEA1, NEA2 and NEA3. The reflective electrode layer REL may contain a reflective material for reflecting light. For example, the reflective material may be metal, but the disclosed technology is not limited thereto. If it can reflect light, any reflective materials may be used. For example, the reflective material may contain titanium Ti/aluminum Al, but the disclosed technology is not limited thereto.

The sixth insulating layer 3f may include an inorganic material such as silicon nitride SiNx, silicon oxide SiOx, or aluminum oxide Al2O3, but the disclosed technology is not limited thereto. The seventh insulating layer 3g′ may include an inorganic material such as silicon nitride SiNx, silicon oxide SiOx, or aluminum oxide Al2O3, but the disclosed technology is not limited thereto.

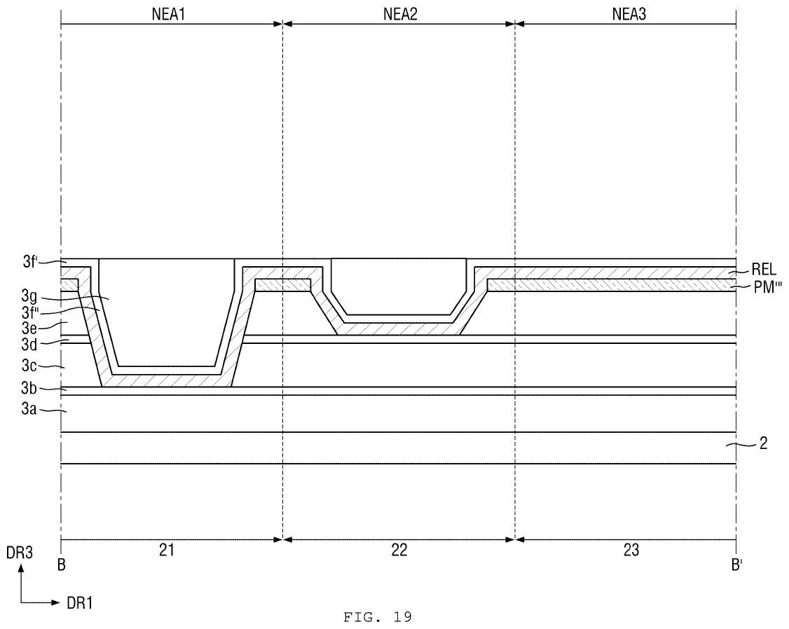

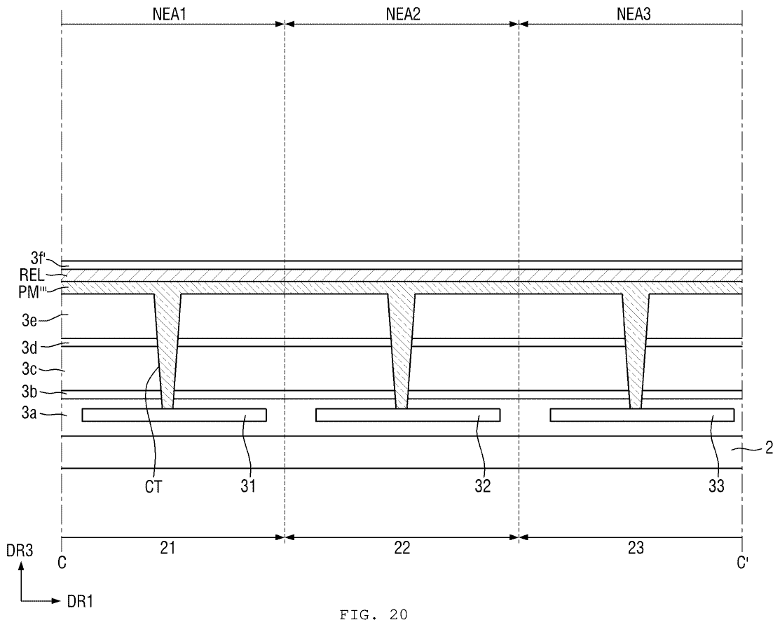

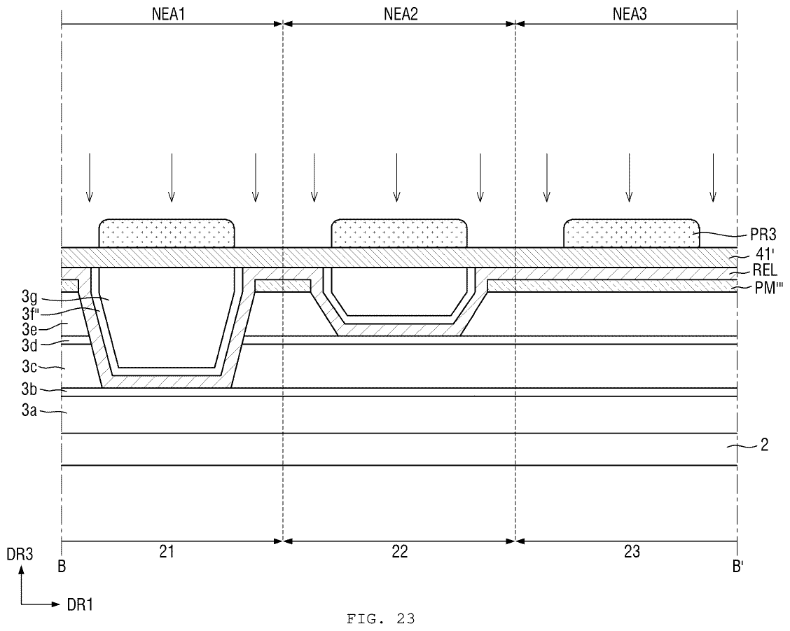

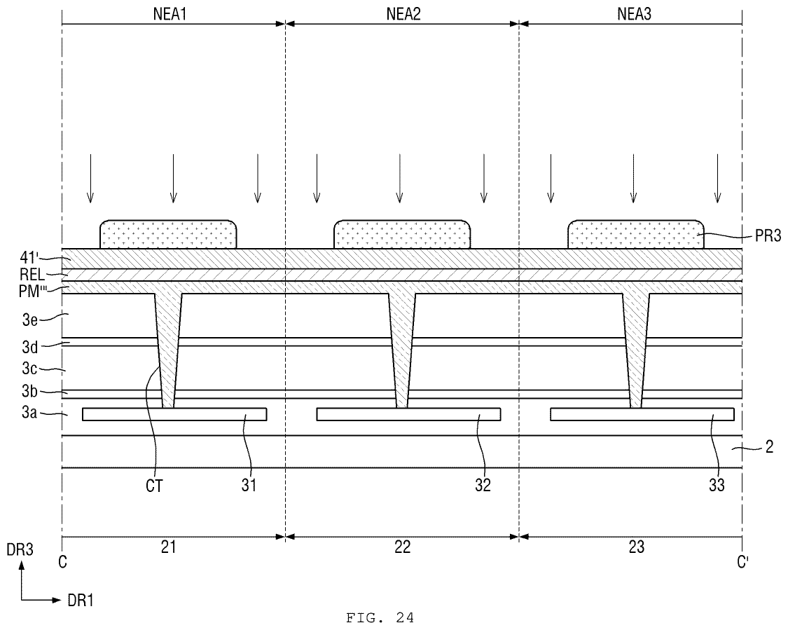

Referring to FIGS. 19 and 20, the seventh insulating layer 3g″ may be polished. The seventh insulating layer 3g″ may be polished through chemical mechanical polishing. Through the chemical mechanical polishing of the seventh insulating layer 3g″, the thickness of the seventh insulating layer 3g″ in the light emitting areas EA1 and EA2 may be reduced, as shown in FIG. 23, and the seventh insulating layer 3g″ in the non-light emitting areas NEA1, NEA2 and NEA3 may be removed, as shown in FIGS. 23 and 24. As shown in FIG. 23, after the seventh insulating layer 3g″ is polished, the surface of the seventh insulating layer 3g″ may be positioned on the same line as the surface of the sixth insulating layer 3f′ on the non-light emitting areas NEA1, NEA2 and NEA3.

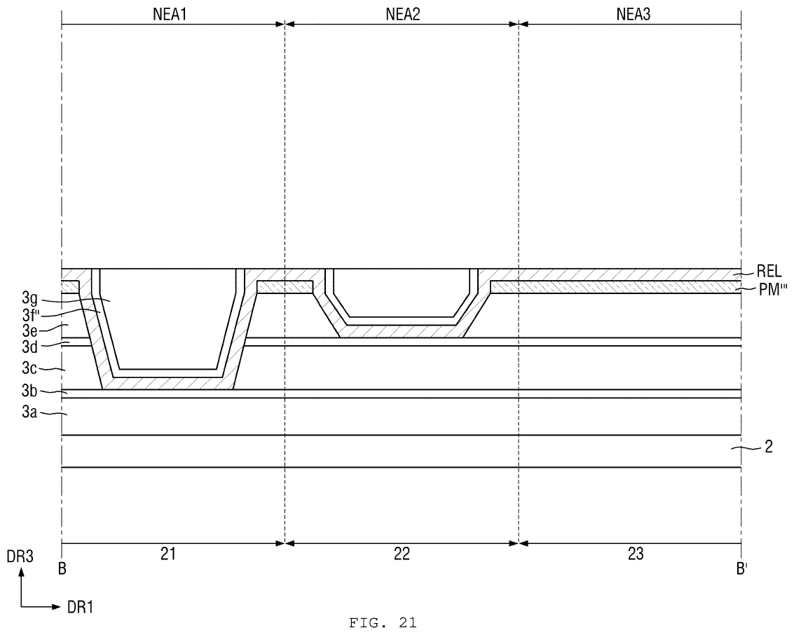

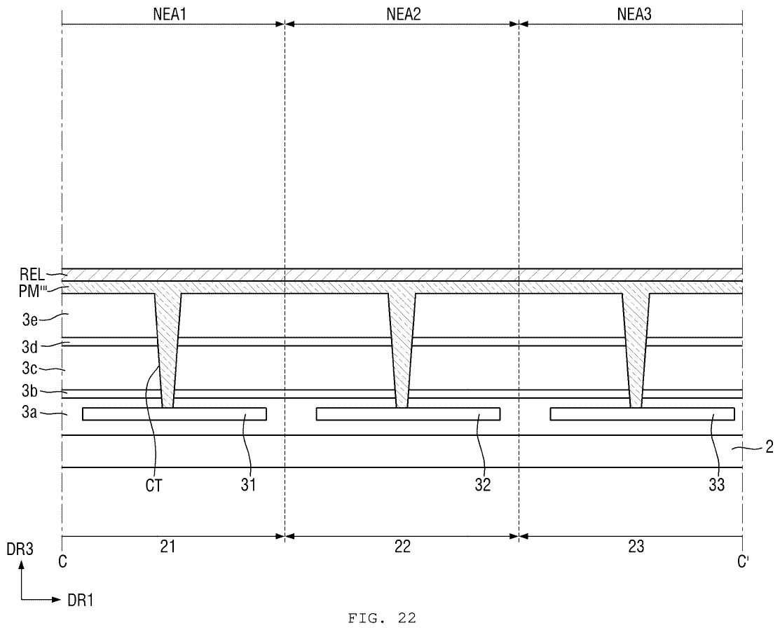

Referring to FIGS. 21 and 22, the sixth insulating layer 3f″ and the seventh insulating layer 3g are formed. The sixth insulating layer 3f″ may be etched from the sixth insulating layer 3f″ of FIGS. 19 and 20, and the seventh insulating layer 3g may be recessed from the seventh insulating layer 3g″ of FIGS. 19 and 20. However, the disclosed technology is not limited thereto. The process of recessing the seventh insulating layer 3g″ may be performed through a cleaning process, but the disclosed technology is not limited thereto. As a result of forming the sixth insulating layer 3f″ and the seventh insulating layer 3g, the sixth insulating layer 3f″ may be removed in the non-light emitting areas NEA1, NEA2 and NEA3, and the thickness of the seventh insulating layer 3g may be reduced in the light emitting areas EA1 and EA2. The surface of the seventh insulating layer 3g may be positioned on the same line as the surface of the sixth insulating layer 3″ and the surface of the protective electrode layer PM′″. The reflective electrode layer REL may be exposed upward in the non-light emitting areas NEA1, NEA2 and NEA3.

Referring to FIGS. 23 and 24, the first electrode layer 41′ may be formed on the seventh insulating layer 3g in the light emitting areas EA1 and EA2, on the reflective layer REL in the third light emitting area EA3 and on the sixth insulating layer 3f″.

The anode electrode layer 41′ may be configured to supply holes to a common light emitting layer 5, as will be described later. The anode electrode layer 41′ may be transparent so that the light reflected from the reflective electrodes 42a, 42b and 42c can travel upward. The anode electrode layer 41′ may include a transparent material, but the disclosed technology is not limited thereto. Any metal materials capable of transmitting light may be provided in the form of a thin film. For example, the anode electrode layer 41′ is made of titanium nitride TiN, but the disclosed technology is not limited thereto. The anode electrode layer 41′ may be a super thin film so that the light reflected from the reflective electrodes 42a, 42b and 42c can travel upward. For example, thickness of the anode electrode layer 41′ may be about 5 nm or less. for another example, the thickness of the anode electrode layer 41′ may be about 3 nm or less, but the disclosed technology is not limited thereto.

A third photoresist PR3 may be formed on the anode electrode layer 41′. The third photoresist PR3 may be formed in the area where the anode electrodes 41a, 41b and 41c of FIGS. 3 and 4 are to be formed, the other area may be exposed.

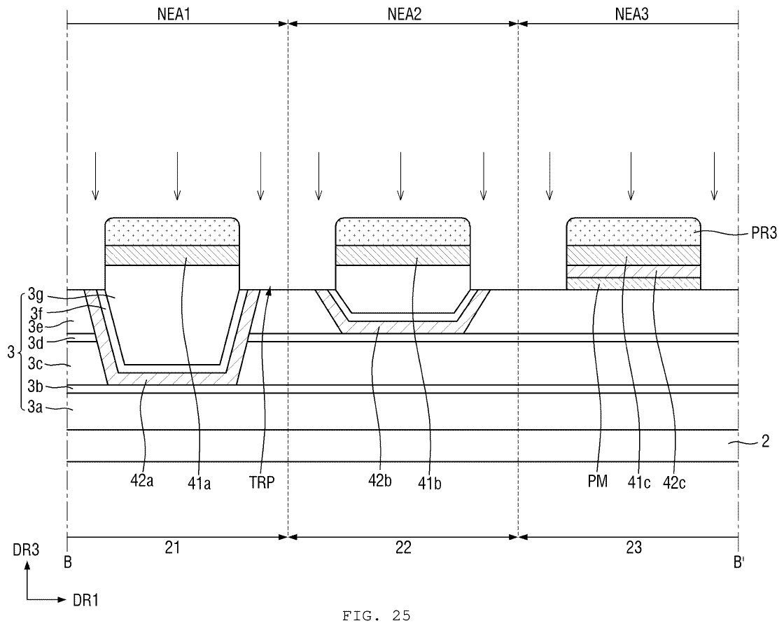

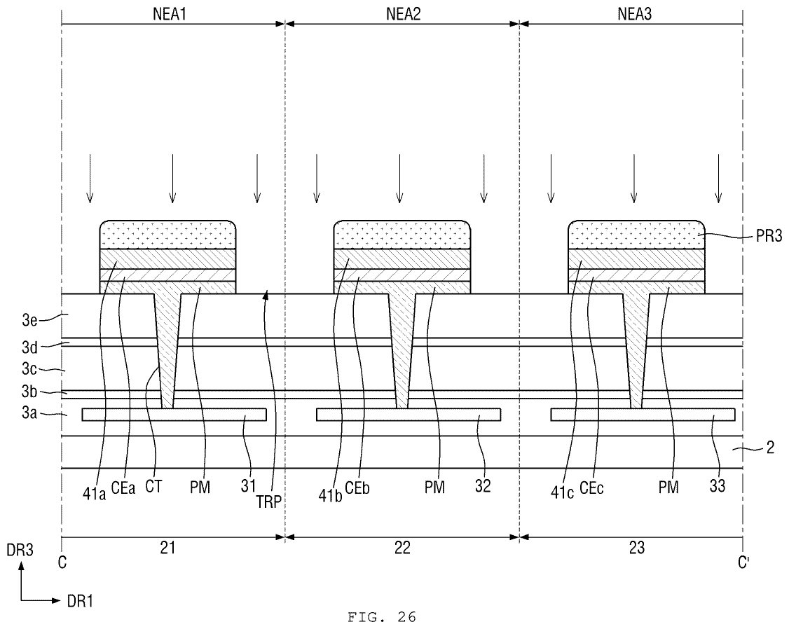

Referring to FIGS. 25 and 26, using the third photoresist PR3 as a mask, the first electrode layer (see 4′ of FIG. 23 and FIG. 24) may be etched for form the first anode electrode 41a, the second anode electrode 41b and the third anode electrode 41c. The etching of the first electrode layer may be dry-etching, but the disclosed technology is not limited thereto.

In some implementations, the reflective electrode layer (e.g., REP in FIGS. 23 and 24), the protective electrode layer (e.g., PM″′ in FIGS. 23 and 24) and the sixth insulating layer (see 3f″ of FIGS. 23 and 24), which are on the non-light emitting areas NEA1, NEA2 and NEA3, may be etched. The etching of the reflective electrode layer (see REL of FIGS. 23 and 24), the protective electrode layer (see PM″′ of FIGS. 23 and 24) and the sixth insulating layer (e.g., 3f″ in FIGS. 23 and 24) may be dry-etching, but the disclosed technology is not limited thereto. As a result of etching the reflective electrode layer (e.g., REL in FIGS. 23 and 24), the protective electrode layer (e.g., PM″′ in FIGS. 23 and 24) and the sixth insulating layer (e.g., 3f″ in FIGS. 23 and 24), the surface of the seventh insulating layer 3g in the first and second light emitting areas EA1 and EA2 may protrude more than the surface of the fifth insulating layer 3e, the surfaces of the reflective electrode 42a and 42b and the surface of the sixth insulating layer 3f. The lateral surface of the area protruding upward more than the surface of the fifth insulating layer 3e, the surfaces of the reflective electrodes 42a and 42b, and the surface of the sixth insulating layer 3f in the seventh insulating layer 3g may be exposed outward. In the third light emitting area EA3, the reflective electrode 42c and the protective electrode PM may be etched by using the same mask as the third anode electrode 41c, thereby having the same width as the third anode electrode 41c, respectively.

In addition, in the non-light emitting areas NEA1, NEA2 and NEA3, the connection electrodes CEa, CEb and CEc may have the same width as the overlapping anode electrodes 41a, 41b and 41c, and the protective electrode PM may have the same width as the overlapping connecting electrodes CEa, CEb and CEc.

As a result of etching the reflective electrode layer (e.g., REL in FIGS. 23 and 24), the protective electrode layer (e.g., PM″′ in FIGS. 23 and 24) and the sixth insulating layer (e.g., 3f″ in FIGS. 23 and 24) on the non-light emitting areas NEA1, NEA2 and NEA3, the trench TRP described in FIGS. 3 and 4 may be formed.

As a result of etching the reflective electrode layer (e.g., REL in FIGS. 23 and 24), the protective electrode layer (e.g., PM″′ in FIGS. 23 and 24) and the sixth insulating layer (e.g., 3f″ in FIGS. 23 and 24) on the non-light emitting areas NEA1, NEA2 and NEA3, the reflective electrodes 42a, 42b and 42c provided in each sub-pixel 21, 22 and 23 may be formed.

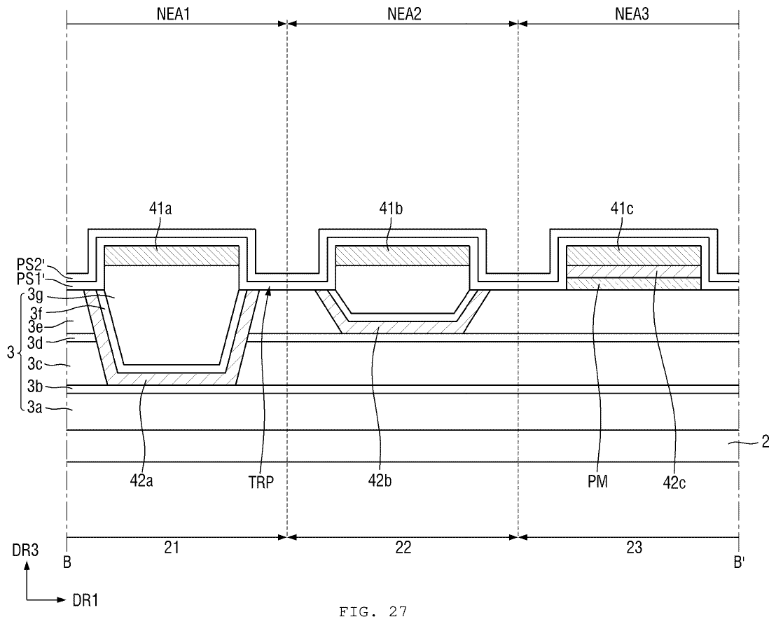

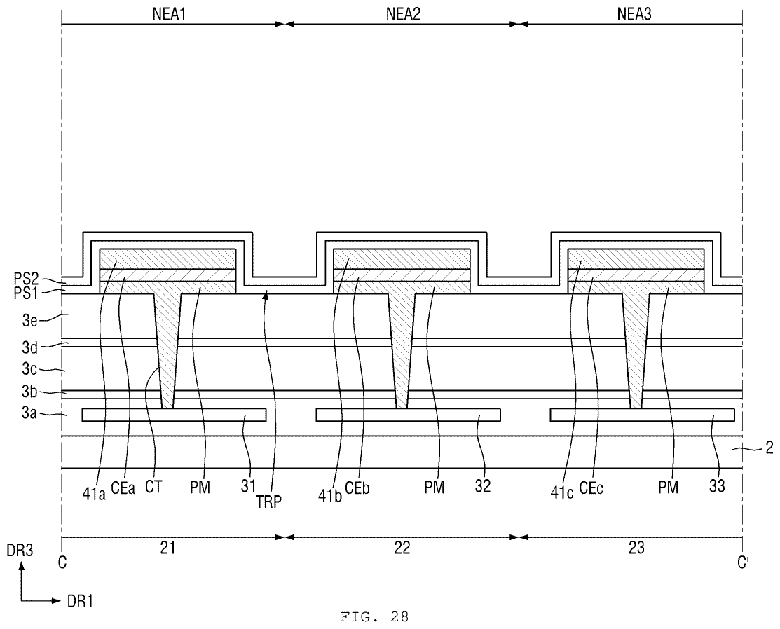

Specifically, in the method for manufacturing the display device 1 according to one embodiment, the etching of the first electrode layer (e.g., 41′ in FIGS. 23 and 24), the formation of the trench TRP and the formation of the reflective electrodes 42a, 42b and 42c may be performed simultaneously by using the third photoresist PR3 as a mask. This has the advantage of reducing the number of masks and simplifying the process. Referring to FIGS. 27 and 28, the first protective layer PS1′ and the second protective layer PS2′ may be formed on the trench TRP and the anode electrodes 41a, 41b and 41c. Each of the first protective layer PS1′ and the second protective layer PS2′ may include inorganic materials such as silicon nitride SiNx, silicon oxide SiOx, or aluminum oxide Al2O3, but the embodiments of the disclosed technology are not limited thereto.

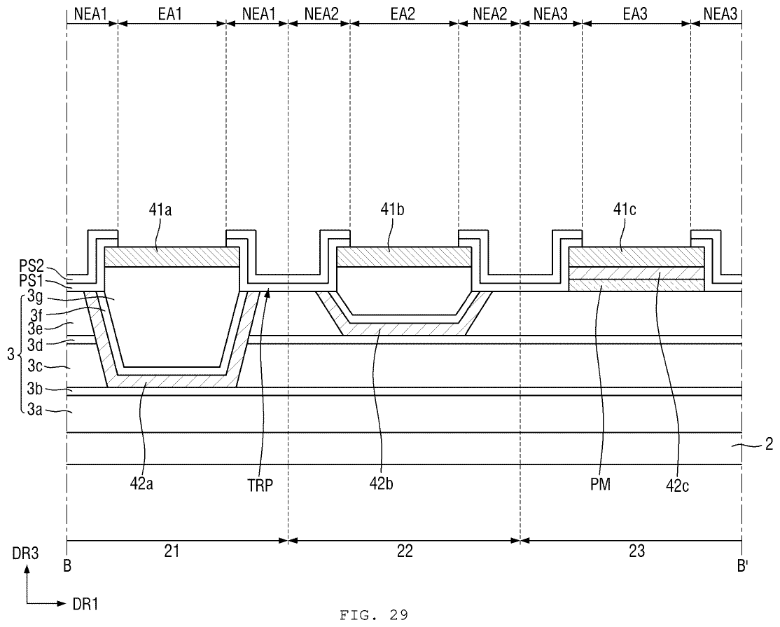

Referring to FIG. 29, the protective layers (e.g., PS1′ and PS2′ in FIG. 27) may be etched in the light emitting areas EA1, EA2 and EA3. The protective layers PS1 and PS2 may be removed in the light emitting areas EA1, EA2 and EA3, to expose the upper surfaces of the anode electrodes 41a, 41b and 41c, but the disclosed technology is not limited thereto. The protective layers PS1 and PC2 on the anode electrodes 411, 41b and 41c disposed on the non-light emitting areas NEA1, NEA2 and NEA3 may not be etched but cover the anode electrodes 41a, 41b and 41c. however, the disclosed technology is not limited thereto.

Hereinafter, display devices according to other embodiments will be described. In describing embodiments below, detailed descriptions or repeated descriptions of configurations and elements that are identical or similar to those described in FIGS. 1 to 29 will be omitted.

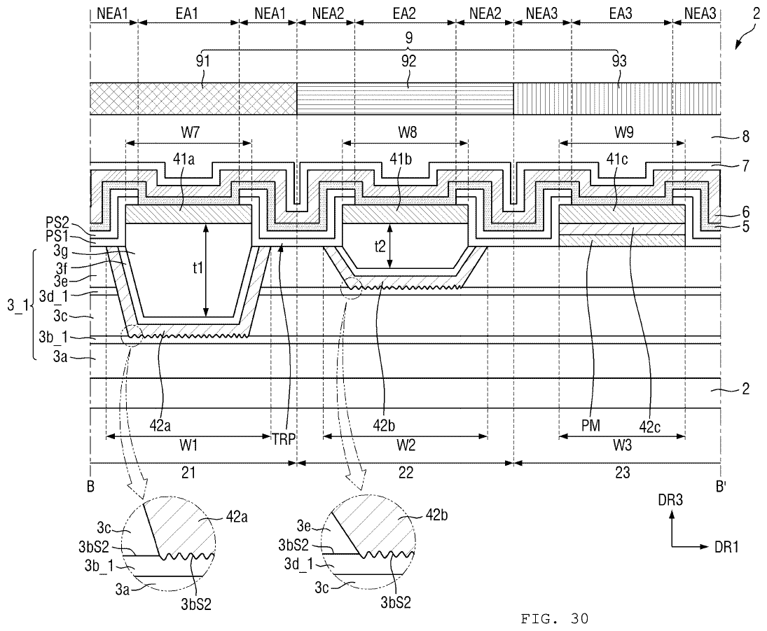

FIG. 30 is a cross-sectional view illustrating a display device based on an embodiment.

Referring to FIG. 30, the display device 2 based on an embodiment may include an insulating layer 3_1, a second insulating layer 3b_1 and a fourth insulating layer 3d_1, different from the display device 1 of FIG. 3.

In some implementations, the second insulating layer 3b_1 may include a first surface 3bs1 overlapping the first insulating layer 3c, and a second surface 3bs2 exposed by the third insulating layer 3c. The fourth insulating layer 3d_2 may include a first surface 3ds1 overlapping the fifth insulating layer 3e, and a second surface 3ds2 exposed by the fifth insulating layer 3e. The roughness of the second surface 3bs2 may be greater than the roughness of the first surface 3bs1. The roughness of the second surface 3ds2 may be greater than the roughness of the first surface 3ds1. In some implementations, by over-etching the second portion 3bP2 during the etching process of FIG. 11 and over-etching the second portion 3dP2 during the etching process of FIG. 15, the roughness of the second surface 3bs2 and 3ds2 may become greater than that of the first surface 3bs1 and 3ds1.

In some implementations, other features of the display device illustrated in FIG. 30 are identical or similar to the display device illustrated in FIGS. 1 to 29.

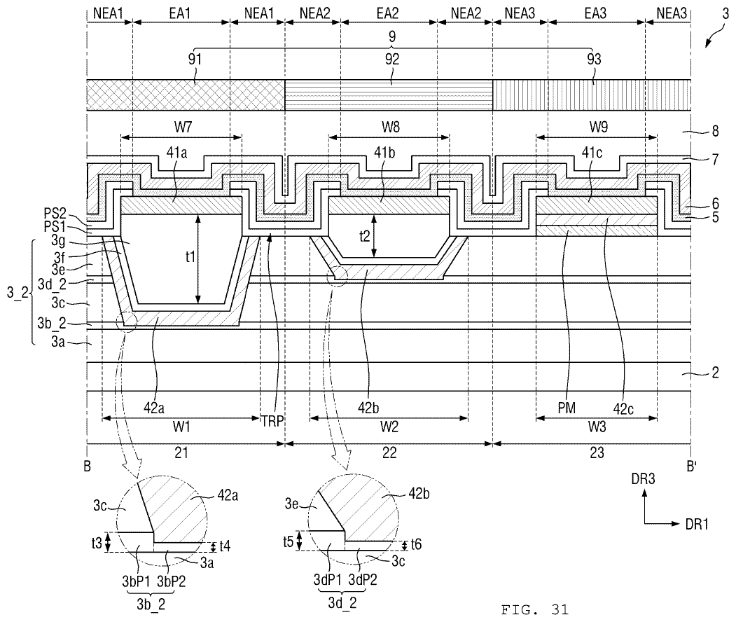

FIG. 31 is a cross-sectional view illustrating a display device based on an embodiment.

Referring to FIG. 31, an insulating layer 3_2 of the display device 3 based on an embodiment may include a second insulating layer 3b_2 and a fourth insulating layer 3d_2, different from the display device 1 of FIG. 3.

In some implementations, the second insulating layer 3b_2 may include a first portion 3bP1 overlapping the third insulating layer 3c, and a second portion 3bP2 exposed by the third insulating layer 3c. The fourth insulating layer 3d_2 may include a first portion 3dP1 overlapping the fifth insulating layer 3e and a second portion 3dP2 exposed by the fifth insulating layer 3e. The thicknesses t3 and t5 of the first portion 3bP1 and 3dP1 may be greater than the thicknesses t4 and t6 of the second portion 3bP2 and 3dP2. In some implementations, by over-etching the second portion 3bP2 during the etching process of FIG. 11 and over-etching the second portion 3dP2 during the etching process of FIG. 15, the thicknesses t3 and t5 of the first portions 3bP1 and 3dP1 may become greater than the thicknesses t4 and t6 of the second portions 3bP2 and 3dP2.

In some implementations, other features of the display device illustrated in FIG. 31 are identical or similar to the display device illustrated in FIGS. 1 to 29.

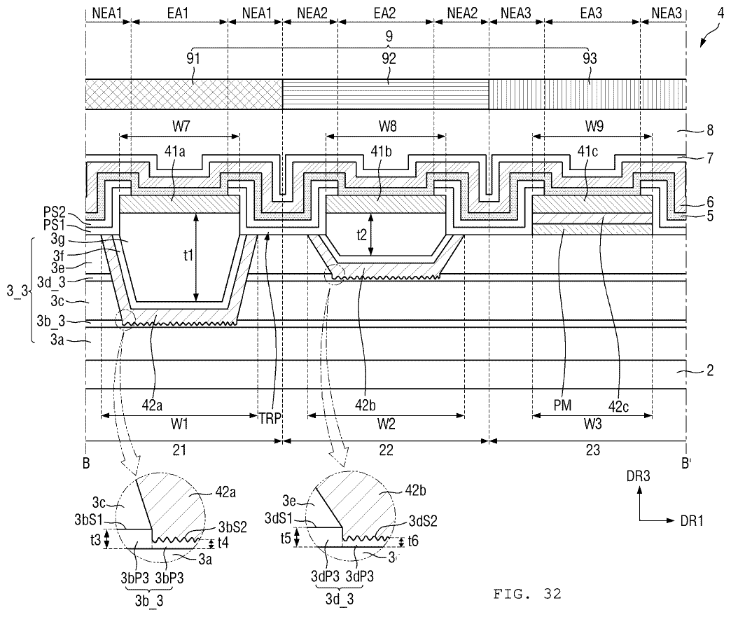

FIG. 32 is a cross-sectional view illustrating a display device based on an embodiment.

Referring to FIG. 32, the insulating layer 3_3 of the display device 4 according to this embodiment may include a second insulating layer 3b_3 and a fourth insulating layer 3d_3, different from the display device 2 of FIG. 30.

More specifically, the second insulating layer 3b_3 may include a first surface 3bs1 overlapping the third insulating layer 3c, and a second surface 3bs2 exposed by the third insulating layer 3c. The fourth insulating layer 3d_3 may include a first surface 3ds1 overlapping the fifth insulating layer 3e and a second surface 3ds2 exposed by the fifth insulating layer 3e. The roughness of the second surface 3bs2 may be greater than the roughness of the first surface 3bs1. The roughness of the second surface 3ds2 may be greater than the roughness of the second surface 3ds2. In some implementations, by over-etching the second portion 3bP2 during the etching process of FIG. 11 and over-etching the second portion 3dP2 during the etching process of FIG. 15, the roughness of the second surface 3bs2 and 3ds2 may become greater than that of the first surface 3bs1 and 3ds1.

In addition, the second insulating layer 3b_3 may include a first portion 3bP1 overlapping the third insulating layer 3c, and a second portion 3bP2 exposed by the third insulating layer 3c. The fourth insulating layer 3d_3 may include a first portion 3dP1 overlapping the fifth insulating layer 3e and a second portion 3dP2 exposed by the fifth insulating layer 3e. The thicknesses t3 and t5 of the first portion 3bP1 and 3dP1 may be greater than the thicknesses t4 and t6 of the second portion 3bP2 and 3dP2. In some implementations, by over-etching the second portion 3bP2 during the etching process of FIG. 11 and over-etching the second portion 3dP2 during the etching process of FIG. 15, the thicknesses t3 and t5 of the first portions 3bP1 and 3dP1 may become greater that the thicknesses t4 and t6 of the second portions 3bP2 and 3dP2.

In some implementations, other features of the display device illustrated in FIG. 32 are identical or similar to the display device illustrated in FIGS. 1 to 29.

A display device based on an embodiment may include a plurality of sub-pixels disposed over a substrate and configured to emit light, the plurality of sub-pixels comprising a first sub-pixel, a second sub-pixel and a third sub-pixel, wherein the first, second, and third sub-pixels include first, second, and third reflective electrodes, respectively, to reflect light, wherein the first reflective electrode and the second reflective electrode have a basket shape.

In an embodiment, a display device may include a substrate comprising a first sub-pixel, a second sub-pixel and a third sub-pixel; a first reflective electrode of the first sub-pixel; a second reflective electrode of the second sub-pixel; and a third reflective electrode of the third sub-pixel. In one example, the first reflective electrode and the second reflective electrode may have a basket shape.

The display device based on an embodiment may further include a first insulating layer disposed between the substrate and the first reflective electrode; and a second insulating layer disposed between the first insulating layer and the first reflective electrode. The first reflective electrode may be disposed directly on the second insulating layer.

In an embodiment, the second insulating layer may include a first surface that does not overlap the first reflective electrode and a second surface that overlaps the first reflective electrode, and the roughness of the second surface may be greater than the roughness of the first surface.

In an embodiment, the second insulating layer may include a first portion that does not overlap the first reflective electrode and a second portion that overlaps the first reflective electrode, and the thickness of the second portion may be less than the thickness of the first portion.

The display device based on an embodiment may further include a third insulating layer disposed between the second insulating layer and the second reflective electrode; and a fourth insulating layer disposed between the third insulating layer and the third reflective electrode. The second reflective electrode may be disposed directly on the fourth insulating layer.

The display device based on an embodiment may include a first surface that does not overlap the second reflective electrode and a second surface that overlap the second reflective electrode, and the roughness of the second surface may be greater than the roughness of the first surface.

In an embodiment, the fourth insulating layer may include a first portion that does not overlap the second reflective electrode and a second portion that overlaps the second reflective electrode, and the thickness of the second portion may be less than the thickness of the first portion.

The display device based on an embodiment may further include a fifth insulating layer disposed on the fourth insulating layer, and the third reflective electrode may be disposed on the fifth insulating layer.

The display device based on an embodiment may further include a protective electrode disposed between the fifth insulating layer and the third reflective electrode in the third sub-pixel, and the width of the protective electrode is the same as the width of the third reflective electrode.

In an embodiment, the first reflective electrode may be disposed to penetrate the fifth insulating layer, and the second reflective electrode may be disposed to penetrate the fifth insulating layer.

In an embodiment, the first reflective electrode may be in direct contact with the third to fifth insulating layers and the second reflective electrode may be in direct contact with the fifth insulating layer.

The display device may further include a first anode electrode disposed on the first reflective electrode, a second anode electrode disposed on the second reflective electrode, and a third anode electrode disposed on the third reflective electrode. The width of the second reflective electrode may be greater than the width of the first anode electrode, the width of the second reflective electrode may be greater than the width of the second anode electrode, and the width of the third reflective electrode may be the same as the width of the third anode electrode.

The display device based on an embodiments may further include a sixth insulating layer each disposed between the first reflective electrode and the first anode electrode and between the second reflective electrode and the second anode electrode; and a seventh insulating layer each disposed between the sixth insulating layer and the first anode electrode and between the sixth insulating layer and the second anode electrode.

In an embodiment, in the first sub-pixel, the width of the first anode electrode may be the same as the width of the seventh insulating layer and in the second sub-pixel, the width of the second anode electrode may be the same as the width of the seventh insulating layer.

The display device based on an embodiment may further include a protective layer disposed on a first anode electrode, a second anode electrode, and the third anode electrode. The protective electrode may partially expose an upper surface of the first anode, an upper surface of the second anode electrode and an upper surface of the third anode electrode.

In an embodiment, the protective layer may be in direct contact with the fifth insulating layer, the first reflective electrode, a sixth insulating layer, the seventh insulating layer and the second reflective electrode.

The display device based on an embodiment may further include a common light emitting layer disposed on the protective layer; a second electrode disposed on the common light emitting layer.

In an embodiment, the first sub-pixel may further include a first transistor positioned at an upper position on the plane of the first reflective electrode, and the second sub-pixel may further include a second transistor positioned at an upper position on the plane of the second reflective electrode. The third sub-pixel may further include third transistor positioned at an upper position on the plane of the second reflective electrode. The second anode electrode may overlap the second transistor, and the third anode electrode may overlap the third transistor.

The display device based on an embodiment may further include a first connection electrode disposed between the first transistor and the first anode electrode; a second connection electrode disposed between the first transistor and the first anode electrode; a second connection electrode disposed between the second transistor and the second anode electrode; and a third connection electrode disposed between the third transistor and the third anode electrode. The first connection electrode and the first reflective electrode may be spaced apart from each other, the second electrode and the second reflective electrode may be spaced apart from each other, and the third connection electrode may be integrally formed with the third reflective electrode.

In some embodiments of the disclosed technology, a method for manufacturing a display device may include: forming, on a substrate, first to third sub-pixels including a light emitting area configured to emit light and a non-light emitting area that does not emit light; forming first to fifth insulating layers on the first to third sub-pixels, wherein the first insulating layer is disposed on the first to third sub-pixels, the second insulating layer is disposed on the first insulating layer, the third insulating layer is disposed on the second insulating layer, the fourth insulating layer is disposed on the third insulating layer, and the fifth insulating layer is disposed on the fourth insulating layer ; forming a protective electrode layer on the fifth insulating layer; etching the protective electrode layer and the third to fifth insulating layers in the first sub-pixel; etching the protective electrode layer and the fifth insulating layer in the second sub-pixel; sequentially forming a reflective electrode layer, a sixth insulating layer and a seventh insulating layer on the protective electrode layer and the fifth insulating layer; exposing the sixth insulating layer in the non-light emitting area by polishing the seventh insulating layer in the first to third sub-pixels; exposing the protective electrode layer in the non-light emitting area by removing the sixth insulating layer and the seventh insulating layer in the first to third sub-pixels; forming a first anode electrode of the first sub-pixel, a second anode electrode of the second sub-pixel and a third anode electrode of the third sub-pixel on the seventh insulating layer; and forming a first reflective electrode of the first sub-pixel, a second reflective electrode of the second sub-pixel and a third reflective electrode of the third sub-pixel by etching the protective electrode layer and the reflective electrode layer in the non-light emitting areas of the first to third sub-pixels, wherein the first reflective electrode and the second reflective electrode have a basket shape.

In an embodiment, forming the first reflective electrode of the first sub-pixel, the second reflective electrode of the second sub-pixel and the third reflective electrode of the third sub-pixel by etching the protective electrode layer and the reflective electrode layer in the non-light emitting areas of the first to third sub-pixels may include forming a protective electrode between the third reflective electrode and the fifth insulating layer in the third sub-pixel, and the width of the protective electrode may be the same as the width of the third reflective electrode.

In an embodiment, the first reflective electrode may be disposed to penetrate the third to fifth insulating layers, and the second reflective electrode is disposed to penetrate the fifth insulating layer.

In an embodiment, the width of the first reflective electrode may be greater than the width of the first anode electrode, the width of the second reflective electrode is greater than the width of the anode electrode, and the width of the third reflective electrode is the same as the width of the third anode electrode.

Only a few implementations and examples are described and other implementations, enhancements and variations can be made based on what is described and illustrated in this patent document.

What is claimed is:

1. A display device comprising:
a plurality of sub-pixels disposed over a substrate and configured to emit light, the plurality of sub-pixels comprising a first sub-pixel, a second sub-pixel and a third sub-pixel,
wherein the first, second, and third sub-pixels include first, second, and third reflective electrodes, respectively, to reflect light, wherein the first reflective electrode and the second reflective electrode have a basket shape.

2. The display device of claim 1, further comprising:
a first insulating layer disposed between the substrate and the first reflective electrode; and
a second insulating layer disposed between the first insulating layer and the first reflective electrode,
wherein the first reflective electrode is disposed directly on the second insulating layer.

3. The display device of claim 2, wherein the second insulating layer comprises a first surface that does not overlap the first reflective electrode and a second surface that overlaps the first reflective electrode, and
wherein a roughness of the second surface is greater than a roughness of the first surface.

4. The display device of claim 2, wherein the second insulating layer comprises a first portion that does not overlap the first reflective electrode and a second portion that overlaps the first reflective electrode, and
wherein a thickness of the second portion is thinner than a thickness of the first portion.

5. The display device of claim 2, further comprising:
a third insulating layer disposed between the second insulating layer and the second reflective electrode; and
a fourth insulating layer disposed between the second insulating layer and the third reflective electrode,
wherein the second reflective electrode is disposed directly on the fourth insulating layer.

6. The display device of claim 5, wherein the fourth insulating layer comprises a first surface that does not overlap the second reflective electrode, and a second surface that overlaps the second reflective electrode, and
wherein a roughness of the second surface is greater than a roughness of the first surface.

7. The display device of claim 5, wherein the fourth insulating layer comprises a first portion that does not overlap the second reflective electrode, and a second portion that overlaps the second reflective electrode, and
wherein a thickness of the second portion is less than a thickness of the first portion.

8. The display device of claim 5, further comprising:
a fifth insulating layer disposed on the fourth insulating layer, wherein the third reflective electrode is disposed on the fifth insulating layer.

9. A display device comprising:
a plurality of sub-pixels disposed over a substrate and configured to emit light, wherein the plurality of sub-pixels includes a first reflective electrode, a second reflective electrode and a third reflective electrode; and
a plurality of anode electrodes including a first anode electrode disposed on the first reflective electrode, a second anode electrode disposed on the second reflective electrode, and a third anode electrode disposed on the third reflective electrode,
wherein a width of the second reflective electrode is greater than a width of the first anode electrode,
the width of the second reflective electrode is greater than a width of the second anode electrode, and
a width of the third reflective electrode is the same as a width of the third anode electrode.

10. The display device of claim 9, further comprising:
a first insulating layer disposed between the substrate and the first reflective electrode, and a second insulating layer disposed between the first insulating layer and the first reflective electrode, wherein the first reflective electrode is directly disposed on the second insulating layer; and
a third insulating layer disposed between the second insulating layer and the second reflective electrode, and a fourth insulating layer disposed between the third insulating layer and the third reflective electrode, wherein the second reflective electrode is disposed directly on the fourth insulating layer.

11. A method for manufacturing a display device comprising:
forming first to third sub-pixels on a substrate including a light emitting area and a non-light emitting area;
forming first to fifth insulating layers on the first to third sub-pixels, wherein the first insulating layer is disposed on the first to third sub-pixels, the second insulating layer is disposed on the first insulating layer, the third insulating layer is disposed on the second insulating layer, the fourth insulating layer is disposed on the third insulating layer, and the fifth insulating layer is disposed on the fourth insulating layer;
forming a protective electrode layer on the fifth insulating layer;
etching the protective electrode layer and the third to fifth insulating layers in the first sub-pixel;
etching the protective electrode layer and the fifth insulating layer in the second sub-pixel;
sequentially forming a reflective electrode layer, a sixth insulating layer and a seventh insulating layer on the protective electrode layer and the fifth insulating layer;
exposing the sixth insulating layer in the non-light emitting area by polishing the seventh insulating layer in the first to third sub-pixels;
exposing the protective electrode layer in the non-light emitting area by removing the sixth insulating layer and the seventh insulating layer in the first to third sub-pixels;
forming a first anode electrode of the first sub-pixel, a second anode electrode of the second sub-pixel and a third anode electrode of the third sub-pixel on the seventh insulating layer; and
simultaneously forming a first reflective electrode of the first sub-pixel, a second reflective electrode of the second sub-pixel and a third reflective electrode of the third sub-pixel by etching the protective electrode layer and the reflective electrode layer in the non-light emitting areas of the first to third sub-pixels,
wherein the first reflective electrode and the second reflective electrode have a basket shape.

12. The method for manufacturing the display device of claim 11, wherein the simultaneously forming the first reflective electrode of the first sub-pixel, the second reflective electrode of the second sub-pixel and the third reflective electrode of the third sub-pixel by etching the protective electrode layer and the reflective electrode layer in the non-light emitting areas of the first to third sub-pixels includes forming a protective electrode between the third reflective electrode of the third sub-pixel and the fifth insulating layer, wherein a width of the protective electrode is the same as a width of the third reflective electrode.

13. The display device of claim 11, wherein the first reflective electrode is disposed to penetrate the third to fifth insulating layers, and the second reflective electrode is disposed to penetrate the fifth insulating layer.

14. The display device of claim 13, wherein a width of the first reflective electrode is greater than a width of the first anode electrode, a width of the second reflective electrode is greater than a width of the second anode electrode, and a width of the third reflective electrode is the same as a width of the third anode electrode.
